(19) United States
(12) Patent Application Publication
(10) Pub. No.: US 2026/0221679 A1
(43) Pub. Date: Jul. 30, 2026

(54) ELECTRICAL CONNECTION STRUCTURE FOR ELECTRONIC COMPONENTS

(71) Applicant: Hirose Electric Co., Ltd., Yokohama (JP)

(72) Inventors: Kota AIZAWA, Yokohama (JP); Tadashi OSHIDA, Yokohama (JP)

(21) Appl. No.: 19/460,117

(22) Filed: Jan. 26, 2026

(30) Foreign Application Priority Data
Jan. 27, 2025 (JP) 2025-011249

(51) Int. Cl. H01R 12/70; H01R 12/72

(52) U.S. Cl. CPC H01R 12/7076; H01R 12/722

(57) ABSTRACT

To make it possible to provide an electrical connection structure for electronic components capable of suppressing an increase in loss occurring during signal transmission even if the distance between a board coupler and an electronic component increases. A connection structure that electrically connects first light modules mounted on a first circuit board and an ASIC mounted on a second circuit board, and also electrically connects the ASIC and second light modules mounted on the second circuit board, wherein the first circuit board and second circuit board are coupled by board couplers; in the board couplers, a first and second intermediate board for cables, while being connected directly to a first and second connector, are connected to counterpart connection portions located in a spaced-apart relationship with the first and second connector; and intermediate boards for connectors are connected directly to both the first connector and the second connector.

### BACKGROUND

### CROSS-REFERENCE TO RELATED APPLICATIONS

This application claims priority to Japanese Patent Application No. 2025-011249, filed January 27, 2025, the contents of which are incorporated herein by reference in its entirety for all purposes.

### Technical Field

The present invention relates to a connection structure for electrically connecting electronic components mounted on different circuit boards.

### Background Art

When electrically connecting electronic components mounted on each of two circuit boards, the two circuit boards may be connected via board couplers provided at multiple locations. In such a connection structure, the electronic components mounted on the respective circuit boards are connected to the board couplers via circuitry (electrically conductive patterns, etc.) formed on the circuit boards.

Connector assemblies, such as the one disclosed in Patent Document 1, are often used as individual board couplers. This connector assembly has board connectors mounted on each of the two circuit boards, and an intermediate connector that provides an intermediate connection between the two board connectors. The intermediate connector comprises multiple intermediate boards arranged side by side in a direction aligned with the major faces of the circuit boards. To these intermediate boards, one board connector is connected from above, and another board connector is connected from below.

### Patent Documents

### Patent Document 1

Japanese Patent Application Publication No. 2023-087854

### SUMMARY

### Problems to be Solved

If a single electronic component is mounted on a circuit board, signal transmission between the multiple board couplers and the electronic component is performed via circuits formed on the circuit board between the respective board couplers and the electronic component. Since at such time the multiple board couplers are disposed at different locations, the distance between a board coupler and the electronic component may be different for different board couplers depending on how the board coupler is disposed. Furthermore, the length of the traces of the above-mentioned circuitry intervening between the respective board couplers and the electronic component will vary depending on the distance between the board couplers and the electronic component. It is common for loss due to heat generation to occur in the circuit traces during signal transmission. The larger the distance between a board coupler and an electronic component, in other words, the longer the traces between a board connector and an electronic component, the higher the loss.

In light of these circumstances, it is an object of the present invention to provide an electrical connection structure for electronic components capable of suppressing an increase in loss occurring during signal transmission even if the distance between a board coupler and an electronic component increases.

### Technical Solution

(1) An electrical connection structure for electronic components according to the present invention is a connection structure that electrically connects a first electronic component mounted on a first circuit board and a second electronic component mounted on a second circuit board, and also electrically connects the second electronic component and a third electronic component mounted on the second circuit board.

In the invention of (1), such an electrical connection structure for electronic components is characterized in that the first circuit board and the second circuit board are coupled by at least one board coupler; the board coupler comprises a first connector mounted on the first circuit board, a second connector mounted on the second circuit board, and an intermediate connector interposed between the first connector and the second connector; the first electronic component is connected to the first connector via circuitry provided on the first circuit board; the intermediate connector of the at least one board coupler comprises at least one intermediate member for linear bodies; a counterpart connection portion corresponding to the intermediate member for linear bodies is mounted on the second circuit board at a location in closer proximity to the second electronic component than the board coupler; the intermediate member for linear bodies, while being connected directly to the first connector, is connected to the counterpart connection portion via a linear body having a signal transmission line; the counterpart connection portion is connected to the second electronic component via circuitry provided on the second circuit board; and the third electronic component is connected to the second electronic component via circuitry provided on the second circuit board.

Generally speaking, loss due to heat generation occurring in a linear body is smaller than loss due to heat generation occurring in the circuit traces (electrically conductive patterns) of a circuit board. In the invention of (1) above, in the board coupler, the intermediate member for linear bodies connected directly to the first connector is connected to the counterpart connection portion via a linear body. The counterpart connection portion is in closer proximity to the second electronic component than the board coupler and is connected to the second electronic component via the circuitry of the second circuit board. Therefore, in the invention of (1) above, a portion of the signal transmission path between the board coupler and the second electronic component is formed by a linear body, which makes it possible to reduce loss due to heat generation compared to when the board coupler and the second electronic component are connected by circuitry.

(2) In the invention of (1), the intermediate connector may comprise, in addition to the intermediate member for linear bodies, at least one intermediate member for connectors, the intermediate member for connectors may be connected directly to the first connector and the second connector, and the second connector may be connected to the second electronic component via circuitry provided on the second circuit board.

(3) In the inventions of (1) or (2), there may be provided a plurality of third electronic components; some of the third electronic components may be connected to the second electronic component via circuitry provided on the second circuit board; the rest of the third electronic components may be connected to the second connector via circuitry provided on the second circuit board; the intermediate connector may comprise, in addition to the intermediate member for linear bodies, at least one other type of intermediate member for linear bodies of a different kind from said intermediate member for linear bodies; another counterpart connection portion corresponding to the other type of intermediate member for linear bodies may be mounted on the second circuit board at a location in closer proximity to the second electronic component than the board coupler; the other type of intermediate member for linear bodies, while being connected directly to the second connector, may be connected to the other counterpart connection portion via a linear body; and the other counterpart connection portion may be connected to the second electronic component via circuitry provided on the second circuit board.

(4) An electrical connection structure for electronic components according to the present invention that is different from the invention of (1) above is a connection structure that electrically connects a first electronic component mounted on a first circuit board and a second electronic component mounted on a second circuit board, and also electrically connects the second electronic component and a third electronic component mounted on the second circuit board.

In the invention of (4), such an electrical connection structure for electronic components is characterized in that the first circuit board and the second circuit board are coupled by at least one board coupler; the board coupler comprises a first connector mounted on the first circuit board, a second connector mounted on the second circuit board, and an intermediate connector interposed between the first connector and the second connector; the first electronic component is connected to the first connector via circuitry provided on the first circuit board; the intermediate connector of the at least one board coupler comprises at least one intermediate member for connectors and at least one intermediate member for linear bodies; a counterpart connection portion corresponding to the intermediate member for linear bodies is mounted on the second circuit board at a location in closer proximity to the second electronic component than the board coupler; the intermediate member for connectors is connected directly to the first connector and the second connector; the second connector is connected to the second electronic component via circuitry provided on the second circuit board; the third electronic component is connected to the second connector via circuitry provided on the second circuit board; the intermediate member for linear bodies, while being connected directly to the second connector, is connected to the counterpart connection portion via a linear body having a signal transmission line; and the counterpart connection portion is connected to the second electronic component via circuitry provided on the second circuit board.

In the invention of (4) above, in the board coupler, the intermediate member for linear bodies connected directly to the second connector is connected to a counterpart connection portion via a linear body. The counterpart connection portion is in closer proximity to the second electronic component than the board coupler and is connected to the second electronic component via the circuitry of the second circuit board. Therefore, in the invention of (4) above, a portion of the signal transmission path between the board coupler and the second electronic component is formed by a linear body, which makes it possible to reduce loss due to heat generation compared to when the board coupler and the second electronic component are connected by circuitry.

(5) In the invention of (4), there may be provided multiple third electronic components; some of the third electronic components may be connected to the intermediate member for linear bodies via the second connector; and the rest of the third electronic components may be connected to the second electronic component via circuitry provided on the second circuit board.

(6) An electrical connection structure for electronic components according to the present invention that is different from the inventions of (1) and (4) above is a connection structure that electrically connects a first electronic component mounted on a first circuit board and a second electronic component mounted on a second circuit board, and also electrically connects the second electronic component and a third electronic component mounted on the second circuit board.

In the invention of (6), such an electrical connection structure for electronic components is characterized in that the first circuit board and the second circuit board are connected by at least one board coupler; the board coupler comprises a first connector mounted on the first circuit board, a second connector mounted on the second circuit board, and an intermediate connector interposed between the first connector and the second connector; the first electronic component is connected to the first connector via circuitry provided on the first circuit board; the intermediate connector of the at least one board coupler comprises at least one of each of two types of intermediate member for linear bodies; a counterpart connection portion corresponding to each type of intermediate member for linear bodies is mounted on the second circuit board at a location in closer proximity to the second electronic component than the board coupler; of the two types of intermediate member for linear bodies, one type of intermediate member for linear bodies, while being connected directly to the first connector, is connected to the counterpart connection portion via a linear body having a signal transmission line, and the other type of intermediate member for linear bodies, while being connected directly to the second connector, is connected to the counterpart connection portion via a linear body having a signal transmission line; the third electronic component is connected to the second connector via circuitry provided on the second circuit board; and the counterpart connection portion is connected to the second electronic component via circuitry provided on the second circuit board.

In the invention of (6) above, the two types of intermediate member for linear bodies in the board coupler, i.e., one type of intermediate member for linear bodies that is connected directly to the first connector, and the other type of intermediate member for linear bodies that is connected directly to the second connector, are each connected to a counterpart connection portion via a linear body. The counterpart connection portion is in closer proximity to the second electronic component than the board coupler and is connected to the second electronic component via the circuitry of the second circuit board. Accordingly, in the invention of (6) above, a portion of the signal transmission path between the board coupler and the second electronic component is formed by a linear body, which makes it possible to reduce loss due to heat generation compared to when the board coupler and the second electronic component are connected by circuitry.

(7) In the invention of (6) the intermediate connector may comprise, in addition to the two types of intermediate member for linear bodies, at least one intermediate member for connectors; the intermediate member for connectors may be connected directly to the first connector and the second connector; the second connector may be connected to the second electronic component via circuitry provided on the second circuit board; there may be provided multiple first electronic components; some of the first electronic components may be connected to the one type of intermediate member for linear bodies via the first connector; and the rest of the first electronic components may be connected to the intermediate member for connectors via the first connector.

(8) In the inventions of (6) or (7), there may be provided multiple third electronic components, some of the third electronic components may be connected to the other type of intermediate member for linear bodies via the second connector, and the rest of the third electronic components may be connected to the second electronic component via circuitry provided on the second circuit board.

### Technical Effect

The present invention can provide an electrical connection structure for electronic components capable of suppressing an increase in loss occurring during signal transmission even if the distance between an electronic component and a board coupler is increased.

### BRIEF DESCRIPTION OF DRAWINGS

FIG. 1 is a perspective view illustrating an electrical connection structure for two electronic components in an embodiment of the present embodiment.

FIG. 2 is a perspective view illustrating a portion of the electrical connection structure for two electronic components shown in FIG. 1.

FIG. 3 is a perspective view of a board coupler, illustrating a first connector, an intermediate connector, and a second connector immediately prior to mating.

FIG. 4 is a perspective view illustrating each member of the second connector in isolation.

FIG. 5 is a perspective view illustrating each member of the intermediate connector in isolation, showing the members as viewed from above.

FIG. 6 is a perspective view illustrating each member of the intermediate connector in isolation, showing the members as viewed from below.

FIGS. 7(A) and 7(B) are perspective views of a first intermediate body for cables, where FIG. 7(A) shows the body as viewed from one side, and FIG. 7(B) as viewed from the other side.

FIGS. 8(A) and 8(B) are perspective views of a first intermediate board for cables, where FIG. 8(A) shows the board as viewed from one side, and FIG. 8(B) as viewed from the other side.

FIGS. 9(A) and 9(B) are perspective views of a second intermediate body for cables, where FIG. 9(A) shows the body as viewed from one side, and FIG. 9(B) as viewed from the other side.

FIGS. 10(A) and 10(B) are perspective views of a second intermediate board for cables, where FIG. 10(A) shows the board as viewed from one side, and FIG. 10(B) as viewed from the other side.

FIGS. 11(A) and 11(B) are perspective views of an intermediate board for connectors, where FIG. 11(A) shows the board as viewed from one side, and FIG. 11(B) as viewed from the other side.

FIG. 12 is a perspective view of a counterpart intermediate connector and a counterpart board connector, showing the connectors immediately prior to mating.

FIG. 13 is a perspective view illustrating each member of the counterpart board connector in isolation.

FIGS. 14(A) and 14(B) are perspective views of a counterpart intermediate body, where FIG. 14(A) shows the body as viewed from one side, and FIG. 14(B) as viewed from the other side.

FIGS. 15(A) and 15(B) are perspective views of a counterpart intermediate board, where FIG. 15(A) shows the board as viewed from one side, and FIG. 15(B) as viewed from the other side.

FIG. 16 is a perspective view illustrating an electrical connection structure for connecting two electronic components used in a variation.

FIG. 17 is a perspective view illustrating a portion of the electrical connection structure for connecting two electronic components shown in FIG. 16.

### DETAILED DESCRIPTION

Embodiments of the present invention are described hereinbelow with reference to the accompanying drawings.

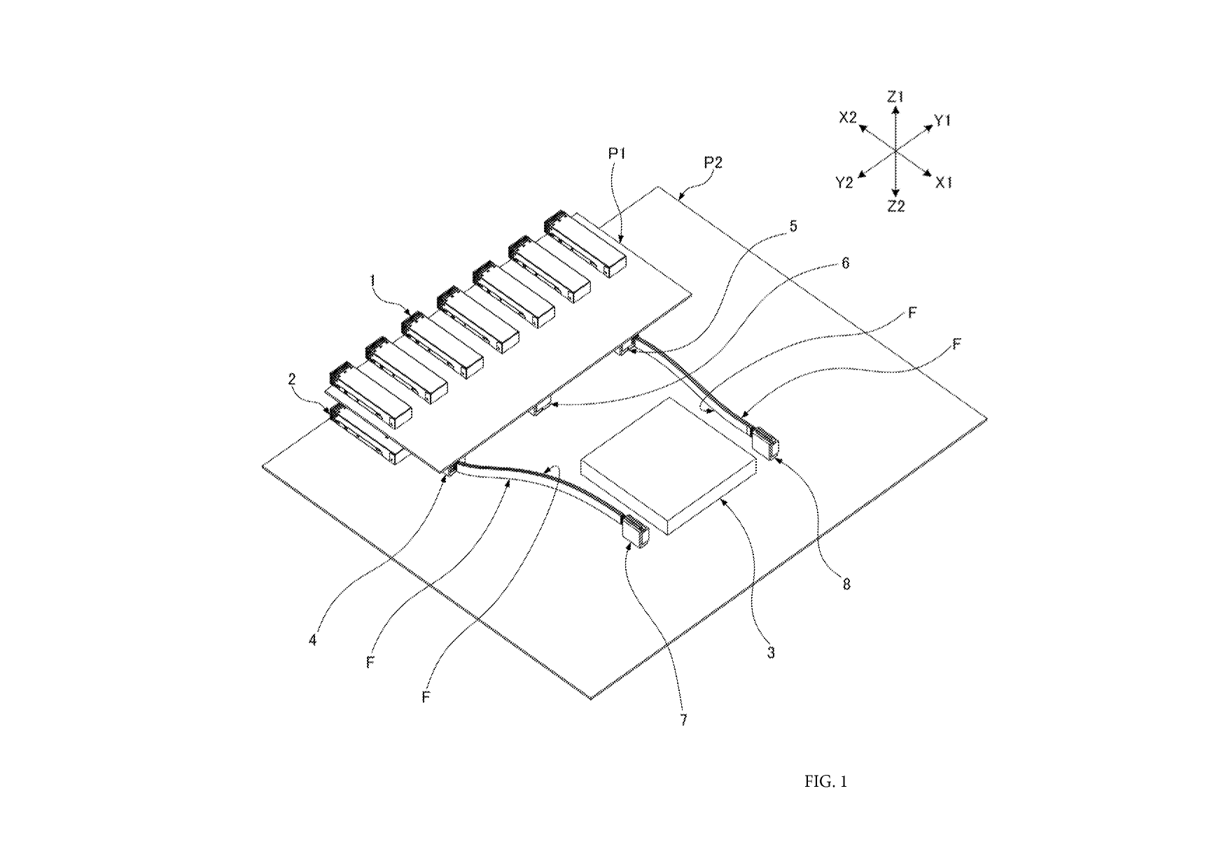

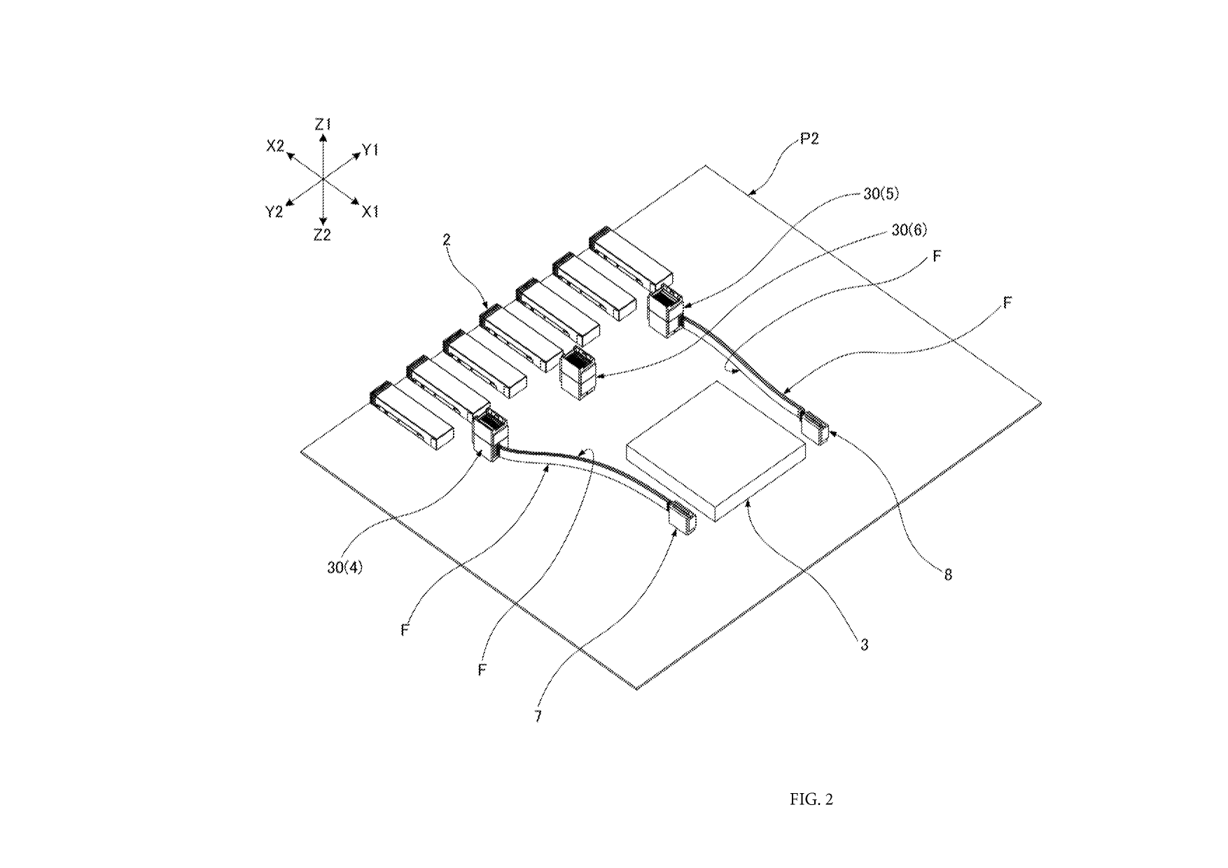

FIG. 1 is a perspective view illustrating an electrical connection structure for connecting two electronic components used in the present embodiment. FIG. 2 is a perspective view illustrating a portion of the electrical connection structure for connecting two electronic components shown in FIG. 1. As shown in FIG. 1 and FIG. 2, in the electrical connection structure of the present embodiment, multiple first light modules 1 serving as first electronic components mounted on a first circuit board P1 (hereinafter referred to as “first circuit board P1”) and multiple second light modules 2 serving as third electronic components mounted on a second circuit board P2 (hereinafter referred to as “second circuit board P2”), as well as a single ASIC (Application-Specific Integrated Circuit) 3 serving as a second electronic component mounted on the second circuit board P2, are adapted to be electrically connected. In the present embodiment, this electrical connection structure is adapted for transmission of differential signals. Hereinbelow, if necessary, the first light modules 1 and the second light modules 2 are referred to collectively as “light modules 1, 2”. In addition, in the present embodiment, the X-axis direction is the forward-backward direction, with the X1 direction being “forward”, and the X2 direction being “backward”.

The major faces of the first circuit board P1 and the second circuit board P2 are in a face-to-face relationship in the up-down direction (Z-axis direction), with the first circuit board P1 being disposed above the second circuit board P2. The light modules 1, 2 are configured as photoelectric conversion modules that perform conversion between optical signals and electrical signals. As shown in FIG. 1, the multiple (in the present embodiment, seven) first light modules 1 are arranged side by side on the top face of the rear portion (portion on the X2 side) of the first circuit board P1 such that the Y-axis direction is the array direction. In FIG. 2, the first circuit board P1 and the first light modules 1 have been omitted from the electrical connection structure of FIG. 1. As shown in FIG. 2, the multiple (in the present embodiment, seven) second light modules 2 are arranged side by side on the top face of the rear portion of the second circuit board P2 (portion on the X2 side) such that the Y-axis direction is the array direction. The multiple second light modules 2 are located directly below the multiple first light modules 1.

As shown in FIG. 1 and FIG. 2, the ASIC 3 has a generally rectangular parallelepiped-like external shape and is mounted on the top face of the front portion (portion on the X1 side) of the first circuit board P1. The ASIC 3 is located within the array range of the light modules 1, 2 in the Y-axis direction.

The first circuit board P1 and the second circuit board P2 are coupled via multiple (in the present embodiment, three) board couplers 4, 5, 6. As shown in FIG. 1, the board couplers 4, 5, 6 are arranged side by side within the bounds of the front portion (portion on the X1 side) of the first circuit board P1 such that the Y-axis direction is the array direction. All first light modules 1 are connected to one of the board couplers 4, 5, 6 via circuitry (not shown) formed by electrically conductive patterns on the first circuit board P1.

Among the multiple second light modules 2, some of the second light modules 2 are connected to one of the board couplers 4, 5 via circuitry (not shown) formed by electrically conductive patterns on the second circuit board P2. In addition, the rest of the second light modules 2 are connected to the ASIC 3 via other circuitry (not shown) formed by electrically conductive patterns on the second circuit board P2.

Among the board couplers 4, 5, 6, the board coupler 6 has the sole function of serving as an intermediary to electrically connect the first circuit board P1 and the second circuit board P2. On the other hand, among the board couplers 4, 5, 6, the board couplers 4, 5, in addition to the functionality possessed by the board coupler 6, have the function of serving as intermediaries to electrically connect the first circuit board P1 and the hereinafter described counterpart connectors 7, 8, and the function of serving as intermediaries to electrically connect the second circuit board P2 and the counterpart connector 7.

The two counterpart connectors 7, 8 are mounted on the top face of the front portion (portion on the X1 side) of the second circuit board P2. The counterpart connectors 7, 8, which are in close proximity to the ASIC 3 at locations flanking the front portion of the ASIC 3 in the Y-axis direction, are connected to the ASIC 3 by circuitry formed by electrically conductive patterns on the second circuit board P2. In this manner, the counterpart connectors 7, 8 are spaced apart from the board couplers 4, 5, 6 and, at the same time, located in closer proximity to the ASIC 3 than the board couplers 4, 5, 6. The counterpart connector 7, which is located farther on the Y2 side than the ASIC 3, is connected to the board coupler 4 via two flat cables F. The counterpart connector 8, which is located farther on the Y1 side than the ASIC 3, is connected to the board coupler 5 via two other flat cables F. Furthermore, no flat cables F are connected to the board coupler 6.

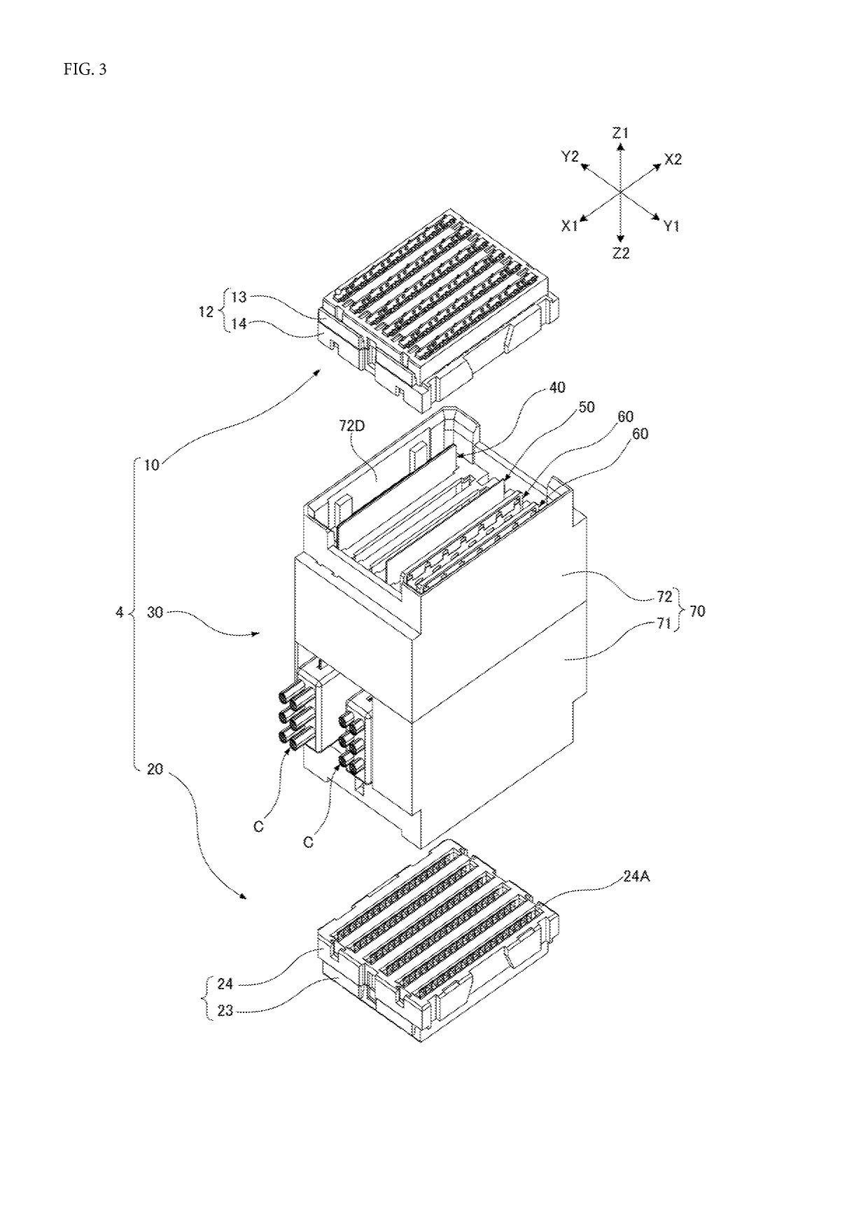

The flat cables F are formed by encasing cables C serving as the hereinafter described multiple linear bodies (see FIG. 3) together within a flat sheath. The cables C are exposed from both ends of the flat cables F. In the present embodiment, all cables C are formed of the same length.

As shown in FIG. 3, the board coupler 4 has a first connector 10, i.e., an electrical connector for circuit boards, which is mounted on the bottom face of the first circuit board P1, a second connector 20, i.e., an electrical connector for circuit boards, which is mounted on the top face of the second circuit board P2, and an intermediate connector 30, which is interposed between the first connector 10 and the second connector 20 in the up-down direction. The first connector 10 and the second connector 20, which are identically shaped connectors, are disposed in vertically flipped orientations with respect to each other.

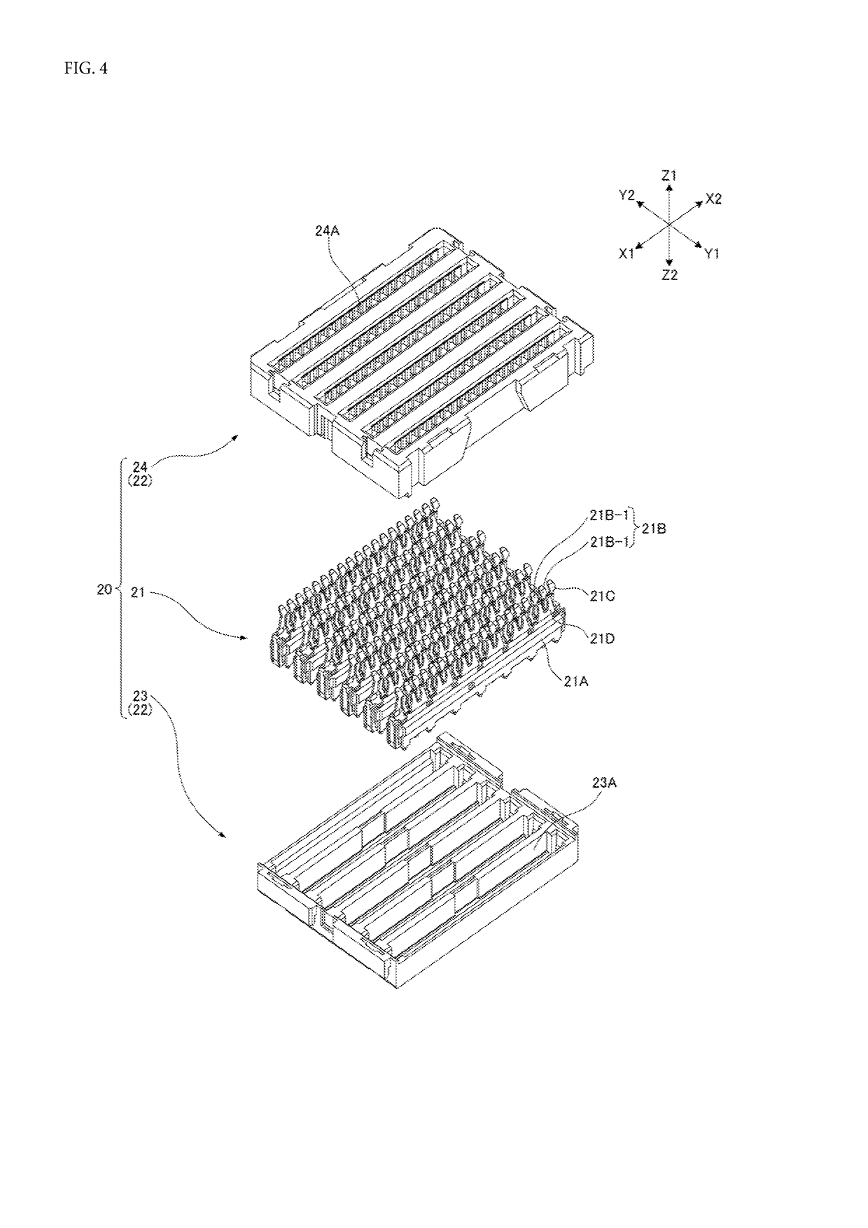

The configuration of the second connector 20 will now be described. As shown in FIG. 4, the second connector 20 has multiple terminal retainers 21 and a housing 22 for retaining these terminal retainers 21.

The multiple (in the present embodiment, six) terminal retainers 21 are provided in a side-by-side arrangement in the Y-axis direction. The terminal retainers 21 have a terminal retaining member 21A made of plastic or another electrically insulating material, multiple signal terminal pairs 21B made of multiple sheet metal plates arranged side by side in the width direction X and retained by the terminal retaining member 21A, as well as a first ground member 21C (corresponding ground portion) and a second ground member 21D (corresponding ground portion) made of sheet metal, which are attached to the major faces (surfaces extending in the XZ directions) on opposite sides of the terminal retaining member 21A. Hereinbelow, the first ground member 21C and the second ground member 21D are referred to collectively as “ground members 21C, 21D” if there is no need to make a distinction between the two.

The terminal retaining member 21A has a plate-like configuration extending across the terminal array range in the longitudinal direction (X-axis direction) of the terminal retainer 21. The terminal retaining member 21A retains the signal terminal pairs 21B and the ground members 21C, 21D in place by integral molding.

The signal terminal pairs 21B have two adjacent signal terminals 21B-1. The signal terminals 21B-1, which are fabricated by bending sheet metal members extending in the up-down direction in the through-thickness direction, are retained by the terminal retaining member 21A in the intermediate portion in the up-down direction. The signal terminals 21B-1 are adapted to be connectable to the intermediate connector 30 by means of arm-shaped signal contact portions that project upwardly from the terminal retaining member 21A and are resiliently displaceable in the through-thickness direction. In addition, the signal terminals 21B-1 are adapted to be solder-connectable to the signal circuitry of the second circuit board P2 by means of leg-shaped signal connection portions projecting downwardly from the terminal retaining member 21A.

In the second connector 20, in the terminal retainers 21 connected to the hereinafter described second intermediate board for cables 51, the signal connection portions of the signal terminals 21B-1 are solder-connected to the signal circuitry of the second circuit board P2. This signal circuitry is connected to the second light modules 2. In addition, in the terminal retainers 21 connected to the hereinafter described intermediate boards for connectors 61 of the intermediate connector 30, the signal connection portions of the signal terminals 21B-1 are solder-connected to the signal circuitry of the second circuit board P2. This signal circuitry is connected to the ASIC 3.

The first ground member 21C, which has a plate-like configuration extending across the terminal array range in the longitudinal direction (X-axis direction) of the terminal retainer 21, is disposed facing the signal terminal pairs 21B from the Y2 side and is retained by the terminal retaining member 21A. The first ground member 21C is adapted to be connectable to the intermediate connector 30 by means of first ground contact portions that project upwardly from the terminal retaining member 21A and are resiliently displaceable in the through-thickness direction. In addition, the first ground member 21C is adapted to be solder-connectable to ground circuitry (not shown) on the second circuit board P2 by means of leg-shaped first ground connection portions (not shown) that project downwardly from the terminal retaining member 21A.

The second ground member 21D, which has a plate-like configuration extending across the terminal array range in the longitudinal direction (X-axis direction) of the terminal retainer 21, is disposed facing the signal terminal pairs 21B from the Y1 side and is retained by the terminal retaining member 21A. The second ground member 21D is adapted to be connectable to the intermediate connector 30 by means of second ground contact portions that project upwardly from the terminal retaining member 21A and are resiliently displaceable in the through-thickness direction. In addition, the second ground member 21D is adapted to be solder-connectable to the ground circuitry (not shown) of the second circuit board P2 by means of leg-shaped second ground connection portions (not shown) that project downwardly from the terminal retainer 21.

As shown in FIG. 3, the housing 22, which is made of plastic or another electrically insulating material, is of a generally rectangular parallelepiped-like external shape. As shown in FIG. 4, the housing 22 includes a lower housing 23 and an upper housing 24, which are formed by being divided in the up-down direction.

Multiple lower accommodating spaces 23A used to accommodate the bottom portions of the terminal retainers 21 are formed in a side-by-side arrangement in the Y-axis direction in the lower housing 23. Along with passing through the lower housing 23 in the up-down direction (Z-axis direction), the lower accommodating spaces 23A extend in the X-axis direction. The lower accommodating spaces 23A receive from above and accommodate the bottom portions of the terminal retainers 21. At such time, the terminal retainers 21 are press-fitted and retained within the lower accommodating spaces 23A using the ends of both ground members 21C, 21D.

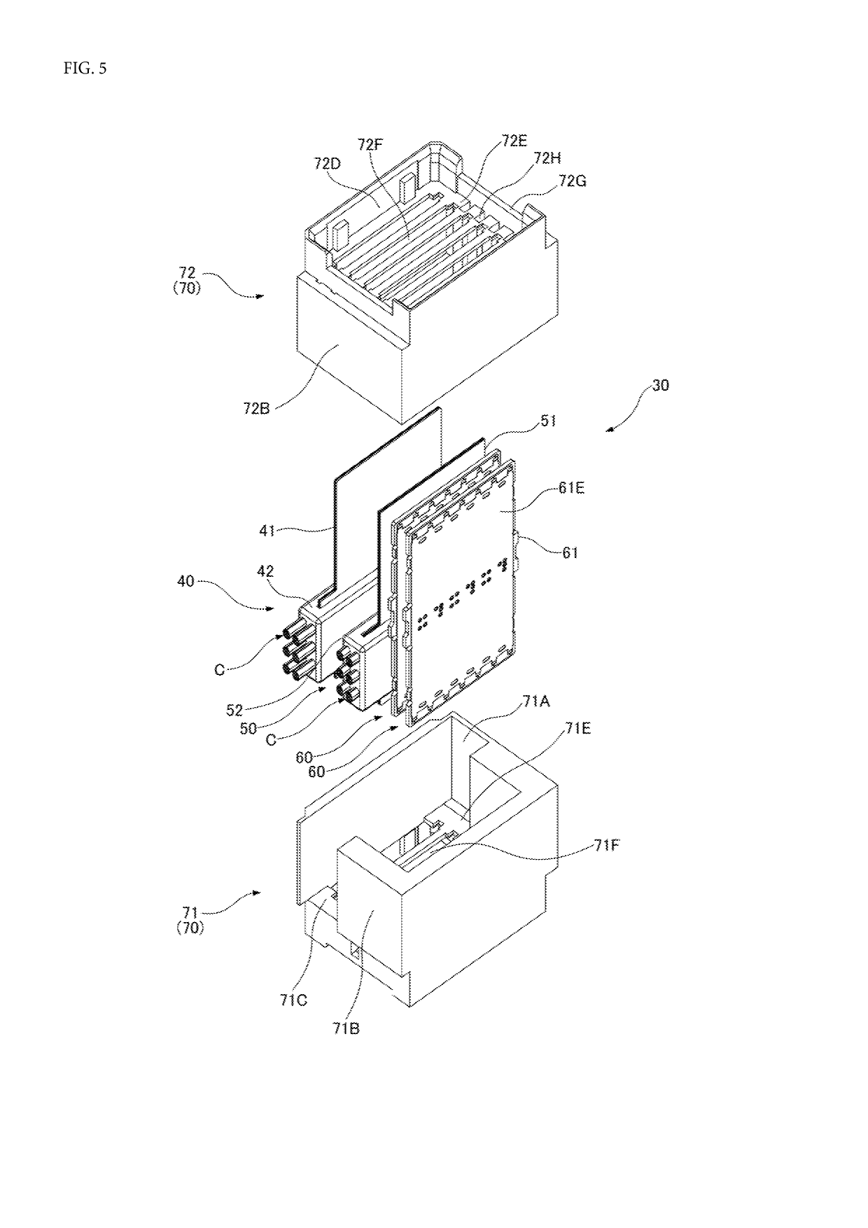

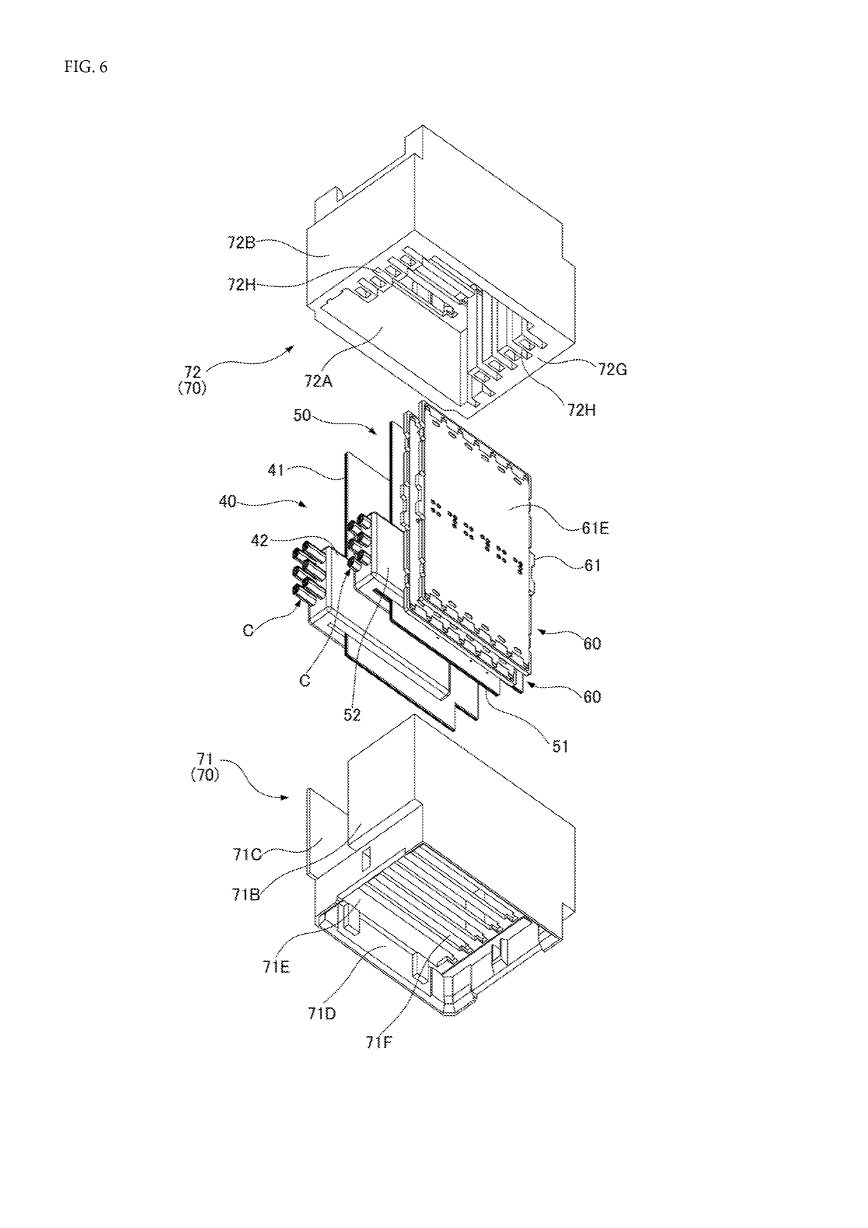

Multiple upper accommodating spaces 24A used to accommodate the top portions of the terminal retainers 21 are formed in a side-by-side arrangement in the Y-axis direction in the upper housing 24. Along with passing through the upper housing 24 in the up-down direction (Z-axis direction), the upper accommodating spaces 24A extend in the X-axis direction. The upper accommodating spaces 24A receive from below and accommodate the top portions of the terminal retainers 21, or more specifically, the signal contact portions of the signal terminals 21B-1 and the ground contact portions of the ground members 21C, 21D. The upper accommodating spaces 24A also serve as receiving spaces that receive, from above, the bottom portions of the hereinafter described intermediate boards 41, 51, 61 (see FIG. 5 and FIG. 6) of the intermediate connector 30.

With respect to the configuration of the first connector 10, as shown in FIG. 3, sections corresponding to the second connector 20 are assigned reference numerals obtained by subtracting “10” from the reference numerals used for the second connector 20, and descriptions thereof are omitted. It should be noted that, in the first connector 10, in the terminal retainers connected to the hereinafter described first intermediate board for cables 41 of the intermediate connector 30, the signal connection portions of the signal terminals are solder-connected to the signal circuitry of the first circuit board P1. This signal circuitry is connected to the first light modules 1. In addition, in the terminal retainers connected to the hereinafter described intermediate boards for connectors 61 of the intermediate connector 30, the signal connection portions of the signal terminals are solder-connected to the signal circuitry of the first circuit board P1. This signal circuitry is also connected to the first light modules 1.

As shown in FIG. 3, FIG. 5, and FIG. 6, the intermediate connector 30 has multiple intermediate bodies 40, 50, 60 and a housing 70 for retaining the intermediate bodies 40, 50, 60. The intermediate bodies 40, 50, 60 include a first intermediate body for cables 40, a second intermediate body for cables 50, and intermediate bodies for connectors 60. Although in the present embodiment, there is provided one first intermediate body for cables 40, one second intermediate body for cables 50, and two intermediate bodies for connectors 60, the number of the intermediate bodies 40, 50, 60 can be set as appropriate. The intermediate bodies 40, 50, 60 are retained in the housing 70 in a side-by-side arrangement in a direction (in the present embodiment, the Y-axis direction) aligned with both the surface of the first circuit board P1 and the surface of the second circuit board P2.

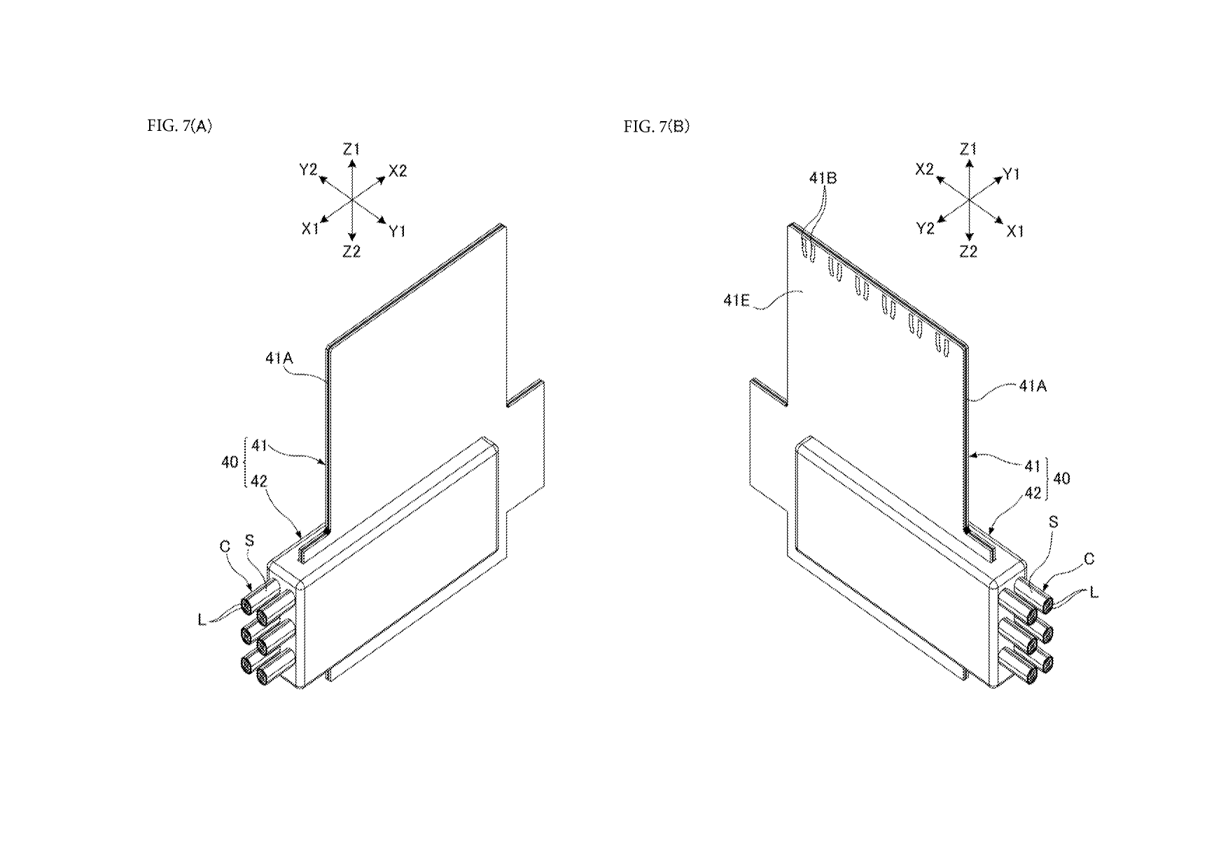

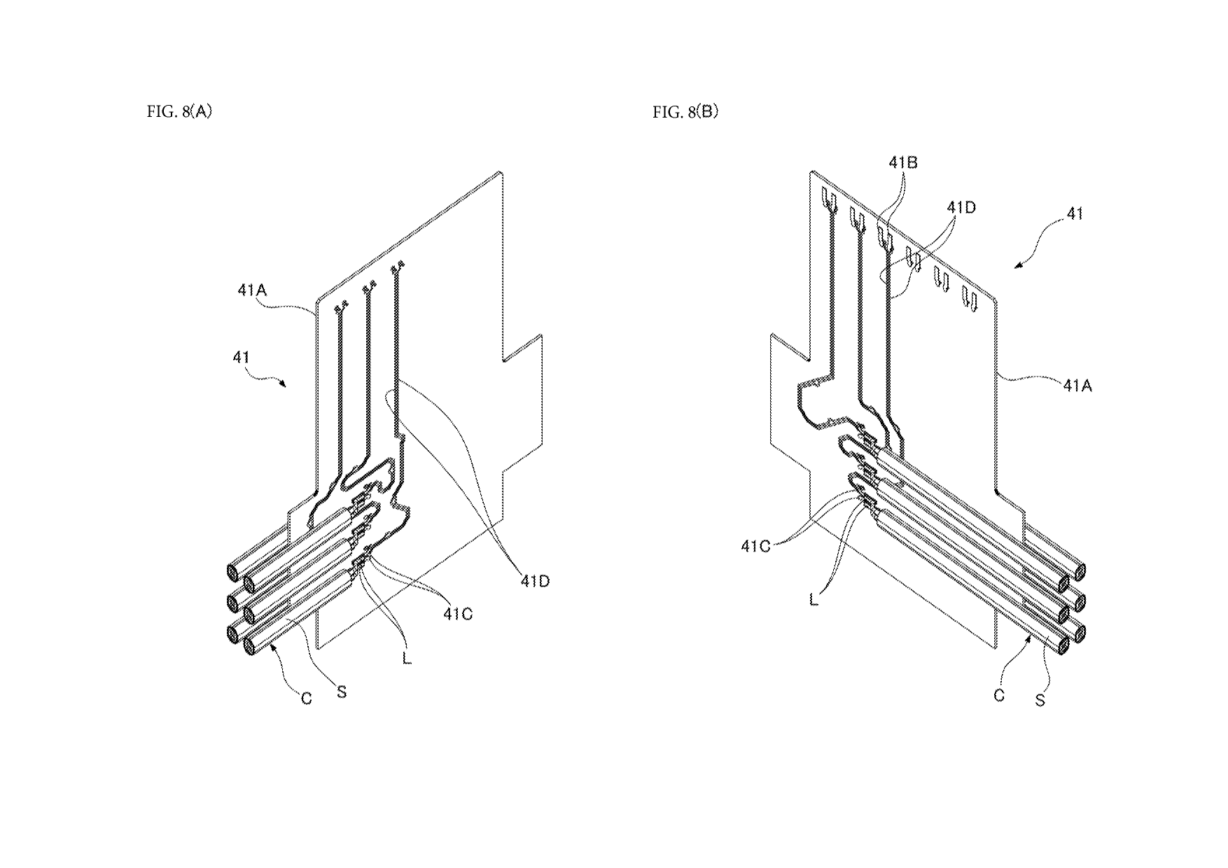

As shown in FIG. 7(A) and FIG. 7(B), the first intermediate body for cables 40 has a first intermediate board for cables 41 (a type of intermediate member for linear bodies) having multiple cables C connected thereto, and a board retaining member 42 retaining the first intermediate board for cables 41. As shown in FIG. 8(A) and FIG. 8(B), the first intermediate board for cables 41 has a plate-shaped substrate 41A, multiple pad pairs for the first connector 41B, multiple pad pairs for cables 41C, multiple trace pairs 41D, and two ground portions 41E (see FIG. 7(A) and FIG. 7(B)).

The substrate 41A, which is made of an electrically insulating material such as plastic, is disposed such that the major faces thereof are at right angles to the Y-axis direction. The substrate 41A is formed of three layers in the Y-axis direction, and, in FIG. 8(A) and FIG. 8(B), the Y1 and Y2 layers have been omitted and only the middle layer is shown. In addition, illustrations of the ground portion 41E that covers the Y1 surface of the substrate, i.e., the Y1 layer (see FIG. 7(A)), and of the ground portion 41E that covers the Y2 surface of the substrate, i.e., the Y2 layer (see FIG. 7(B), have been omitted in FIG. 8(A) and FIG. 8(B).

Multiple (in the present embodiment, six) pad pairs for the first connector 41B are formed in the top portion of the substrate 41A. In the present embodiment, as shown in FIG. 7(B), all pad pairs for the first connector 41B are arranged side by side in the X-axis direction on the Y2 major face of the Y2 layer of the substrate 41A. Therefore, as shown in FIG. 7(A), no pad pairs for the first connector 41B are formed on the Y1 layer of the substrate 41A.

Multiple (in the present embodiment, six) pad pairs for cables 41C are formed in the bottom portion of the substrate 41A. In the present embodiment, as shown in FIG. 8(A), three of the pad pairs for cables 41C are arranged side by side in the up-down direction on the Y1 major face of the Y1 layer (not shown) of the substrate 41A and, as shown in FIG. 8(B), three of the pad pairs for cables 41C are arranged side by side in the up-down direction on the Y2 major face of the Y2 layer (not shown) of the substrate 41A.

As shown in FIG. 8(A), the row of pad pairs formed by three pad pairs for cables 41C on the Y1 side is provided at a more forwardly disposed location (on the X1 side) than the middle point of the first intermediate board for cables 41 in the forward-backward direction (X-axis direction). In addition, as shown in FIG. 8(B), the row of pad pairs formed by three pad pairs for cables 41C on the Y2 side is provided at a more rearward location (on the X2 side) than the row of pad pairs on the Y1 side.

As shown in FIG. 8(A) and FIG. 8(B), cables C are connected to the respective pad pairs for cables 41C. Each cable C is formed by encasing an electrical wire pair L (signal transmission line) having a pair of electrical wires within a sheath S, and is, for example, a twinax cable. Each electrical wire pair L is exposed from the end of the sheath S. In the present embodiment, the electrical wire pairs L exposed in the rear end portions (ends on the X2 side) of the cables C are solder-connected to the pad pairs for cables 41C. The cables C project forwardly (in the X1 direction) from the location of the pad pairs for cables 41C.

The trace pairs 41D are multiple (in the present embodiment, six) pairs of electrically conductive patterns formed on the major faces of the middle layer of the substrate 41A. The multiple trace pairs 41D, which are formed of equal electrical length, connect the pad pairs for the first connector 41B and the pad pairs for cables 41C.

As shown in FIG. 8(A), on the Y1 major face of the middle layer of the substrate 41A, the three trace pairs 41D have mutually different shapes and extend without intersecting each other within the bounds of the front portion of the substrate 41A. As shown in FIG. 8(B), on the Y2 major face of the middle layer of the substrate 41A, the three trace pairs 41D have mutually different shapes and extend without intersecting each other within the bounds of the rear portion of the substrate 41A. The Y1 and Y2 trace pairs 41D are connected by vias to the pad pairs for the first connector 41B and the pad pairs for cables 41C that correspond thereto.

The ground portions 41E are provided to cover most of the respective major faces of the substrate 41A. At such time, neither the pad pairs for the first connector 41B, nor the pad pairs for cables 41C are covered by the ground portions 41E.

As shown in FIG. 7(A) and FIG. 7(B), the board retaining member 42, which has a rectangular parallelepiped-like external shape extending in the forward-backward direction, retains the bottom portion of the first intermediate board for cables 41 in place by integral molding. In addition, the board retaining member 42 embeddedly retains the ends of the cables C in the front portion. The bottom end portion of the first intermediate board for cables 41 protrudes downwardly from the board retaining member 42.

In the thus configured first intermediate body for cables 40, the first intermediate board for cables 41 is mated with the first connector 10 in the top portion. At such time, the first intermediate board for cables 41 is connected to the signal contact portions of the signal terminal pairs of the first connector 10 by means of the pad pairs for the first connector 41B, and is connected to the ground contact portions of the ground members of the first connector 10 by means of the ground portions 41E. In addition, the electrical wire pairs L of the cables C are solder-connected to the pad pairs for cables 41C of the first intermediate board for cables 41. In this manner, the first intermediate board for cables 41 is adapted to relay an electrical connection between the first connector 10 and the cables C.

In addition, the first intermediate board for cables 41 is mated with the second connector 20 by the bottom end portion protruding from the board retaining member 42. At such time, the first intermediate board for cables 41 is connected to the ground contact portions of the ground members 21C, 21D of the second connector 20 by means of the ground portions 41E. In addition, in the present embodiment, the first intermediate board for cables 41, while being in mating engagement with the second connector 20, is placed in contact with, but not electrically connected to, the signal terminal pairs 21B of the second connector 20 in the bottom end portion.

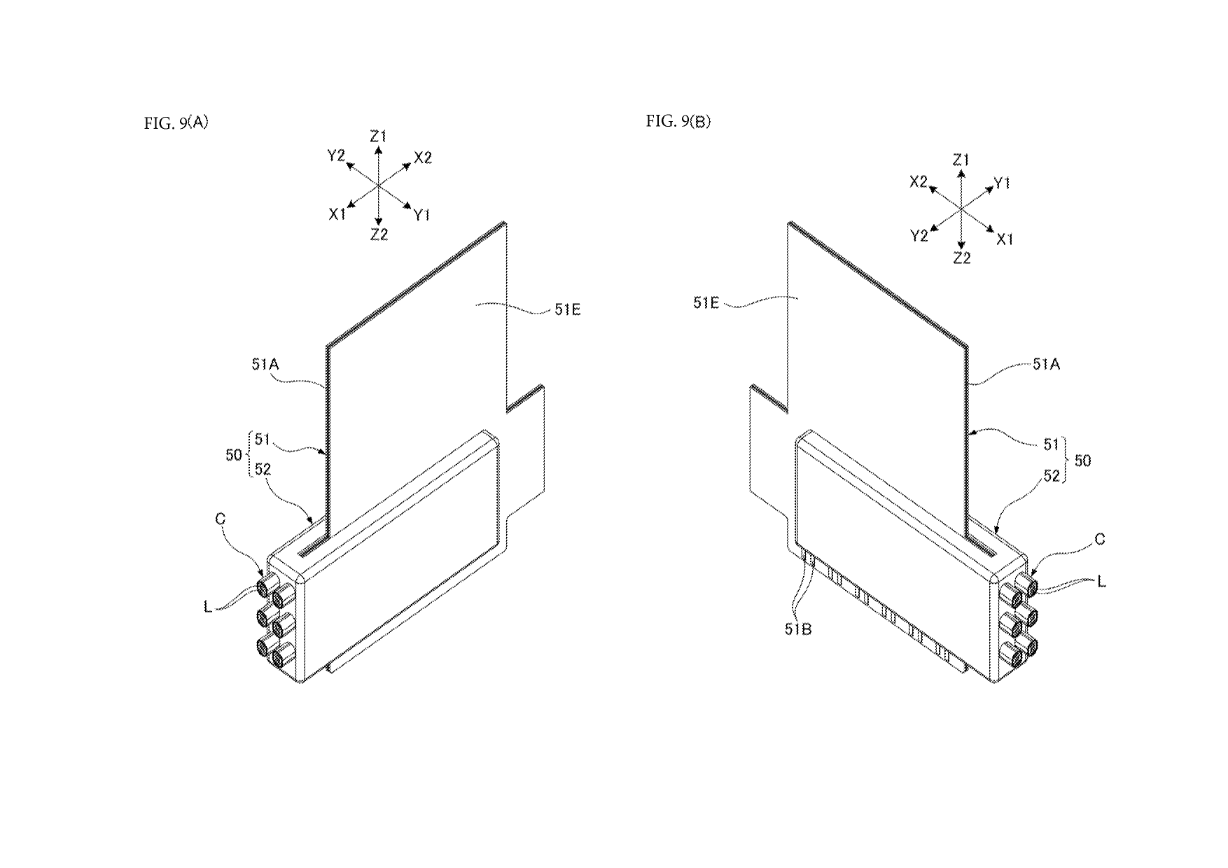

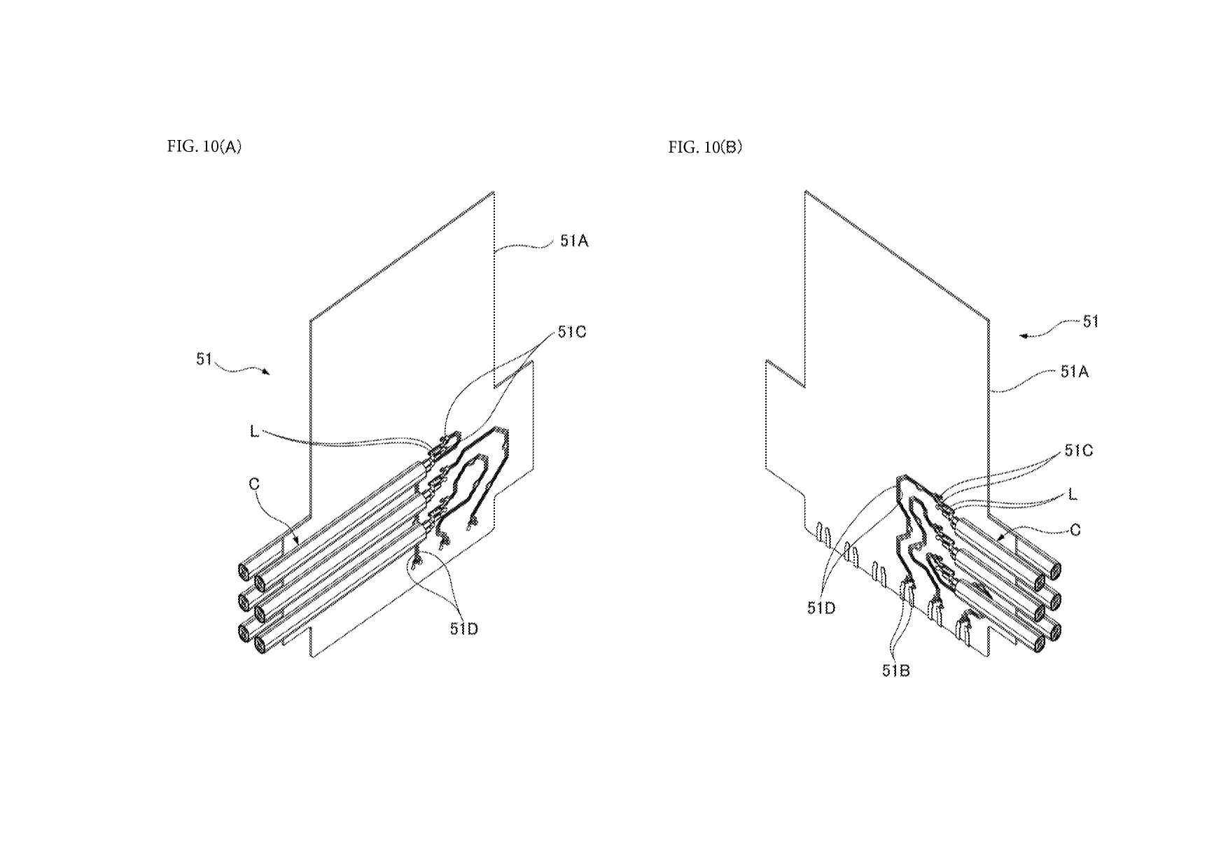

As shown in FIG. 9(A) and FIG. 9(B), the second intermediate body for cables 50 has a second intermediate board for cables 51 (another type of intermediate member for linear bodies), which has multiple cables C connected thereto, and a board retaining member 52, which retains the second intermediate board for cables 51. As shown in FIG. 10(A) and FIG. 10(B), the second intermediate board for cables 51 has a plate-shaped substrate 51A, multiple pad pairs for the second connector 51B, multiple pad pairs for cables 51C, multiple trace pairs 51D, and two ground portions 51E (see FIG. 9(A) and FIG. 9(B)).

The substrate 51A, which is a plate-like member made of plastic or another electrically insulating material of substantially the same shape as the substrate 41A of the first intermediate board for cables 41, is disposed such that the major faces thereof are at right angles to the Y-axis direction. The substrate 51A is formed of three layers in the Y-axis direction, and in FIG. 10(A) and FIG. 10(B), the Y1 and Y2 layers have been omitted and only the middle layer is shown. In addition, illustrations of the ground portion 51E that covers the Y1 surface of the substrate, i.e., the Y1 layer (see FIG. 9(A)), and of the ground portion 51E that covers the Y2 surface of the substrate, i.e., the Y2 layer (see FIG. 9(B), have been omitted in FIG. 10(A) and FIG. 10(B).

Multiple (in the present embodiment, six) pad pairs for the second connector 51B are formed in the bottom portion of the substrate 51A. In the present embodiment, as shown in FIG. 10(B), all pad pairs for the second connector 51B are arranged side by side in the X-axis direction on the Y2 major face of the Y2 layer of the substrate 51A. Therefore, as shown in FIG. 10(A), no pad pairs for the second connector 51B are formed on the Y1 layer of the substrate 51A.

Multiple (in the present embodiment, six) pad pairs for cables 51C are formed in the bottom portion of the substrate 51A. In the present embodiment, as shown in FIG. 10(A), three of the pad pairs for cables 51C are arranged side by side in the up-down direction on the Y1 major face of the Y1 layer (not shown) of the substrate 51A and, as shown in FIG. 10(B), three of the pad pairs for cables 51C are arranged side by side in the up-down direction on the Y2 major face of the Y2 layer (not shown) of the substrate 51A.

As shown in FIG. 10(A), the row of pad pairs formed by three pad pairs for cables 51C on the Y1 side is provided at a slightly more rearwardly disposed location (on the X2 side) than the middle point of the second intermediate board for cables 51 in the forward-backward direction (X-axis direction). In addition, as shown in FIG. 10(B), the row of pad pairs formed by three pad pairs for cables 51C on the Y2 side is provided at a more forward location (on the X1 side) than the row of pad pairs on the Y1 side.

As shown in FIG. 10(A) and FIG. 10(B), cables C are connected to the respective pad pairs for cables 51C. Each cable C is a cable of the same type as the cables connected to the first intermediate board for cables 41. In the present embodiment, the electrical wire pairs L exposed in the rear end portions (ends on the X2 side) of the cables C are solder-connected to the pad pairs for cables 51C. The cables C project forwardly (in the X1 direction) from the location of the pad pairs for cables 51C.

The trace pairs 51D are multiple (in the present embodiment, six) pairs of electrically conductive patterns formed on the major faces of the middle layer of the substrate 51A. The multiple trace pairs 51D are formed of equal electrical length and connect the pad pairs for the second connector 51B and the pad pairs for cables 51C.

As shown in FIG. 10(A), on the Y1 major face of the middle layer of the substrate 51A, the three trace pairs 51D have mutually different shapes and extend without intersecting each other within the bounds of the rear portion of the substrate 51A. As shown in FIG. 10(B), on the Y2 major face of the middle layer of the substrate 51A, the three trace pairs 51D have mutually different shapes and extend without intersecting each other within the bounds of the front portion of the substrate 51A. The Y1 and Y2 trace pairs 51D are connected by vias to the pad pairs for the second connector 51B and the pad pairs for cables 51C that correspond thereto.

The ground portions 51E are provided to cover most of the respective major faces of the substrate 51A. At such time, neither the pad pairs for the second connector 51B, nor the pad pairs for cables 51C are covered by the ground portions 51E.

As shown in FIG. 9(A) and FIG. 9(B), the board retaining member 52, which is of substantially the same shape as the board retaining member 42 of the first intermediate body for cables 40, retains the bottom portion of the second intermediate board for cables 51 in place by integral molding. In addition, the board retaining member 52 embeddedly retains the ends of the cables C in the front portion. The bottom end portion of the second intermediate board for cables 51 protrudes downwardly from the board retaining member 52.

In the thus configured second intermediate body for cables 50, the second intermediate board for cables 51 is mated with the second connector 20 in the bottom end portion, which protrudes from the board retaining member 52. At such time, the second intermediate board for cables 51 is connected to the signal contact portions of the signal terminal pairs 21B of the second connector 20 by means of the pad pairs for the second connector 51B, and is connected to the ground contact portions of the ground members 21C, 21D of the second connector 20 by means of the ground portions 51E. In addition, the electrical wire pairs L of the cables C are solder-connected to the pad pairs for cables 51C of the second intermediate board for cables 51. In this manner, the second intermediate board for cables 51 is adapted to relay an electrical connection between the second connector 20 and the cables C.

In addition, the second intermediate board for cables 51 is mated with the first connector 10 in the top portion. At such time, the second intermediate board for cables 51 is connected to the ground contact portions of the ground members of the first connector 10 by means of the ground portions 51E. In addition, in the present embodiment, the second intermediate board for cables 51, while being in mating engagement with the first connector 10, is brought into contact with, but not electrically connected to, the signal terminal pairs of the first connector 10 in the top portion.

The intermediate bodies for connectors 60 are intermediate boards for connectors 61 (intermediate members for connectors). When viewed in the Y-axis direction, the intermediate boards for connectors 61 are circuit boards of a rectangular parallelepiped-like external shape. Unlike the first intermediate board for cables 41 and the second intermediate board for cables 51, the intermediate boards for connectors 61 are retained by the housing 70 directly, without being retained by the board retaining members. The intermediate boards for connectors 61 have a plate-shaped substrate 61A, multiple pad pairs for the first connector 61B, multiple pad pairs for the second connector 61C, multiple trace pairs 61D, and two ground portions 61E (see FIG. 5 and FIG. 6).

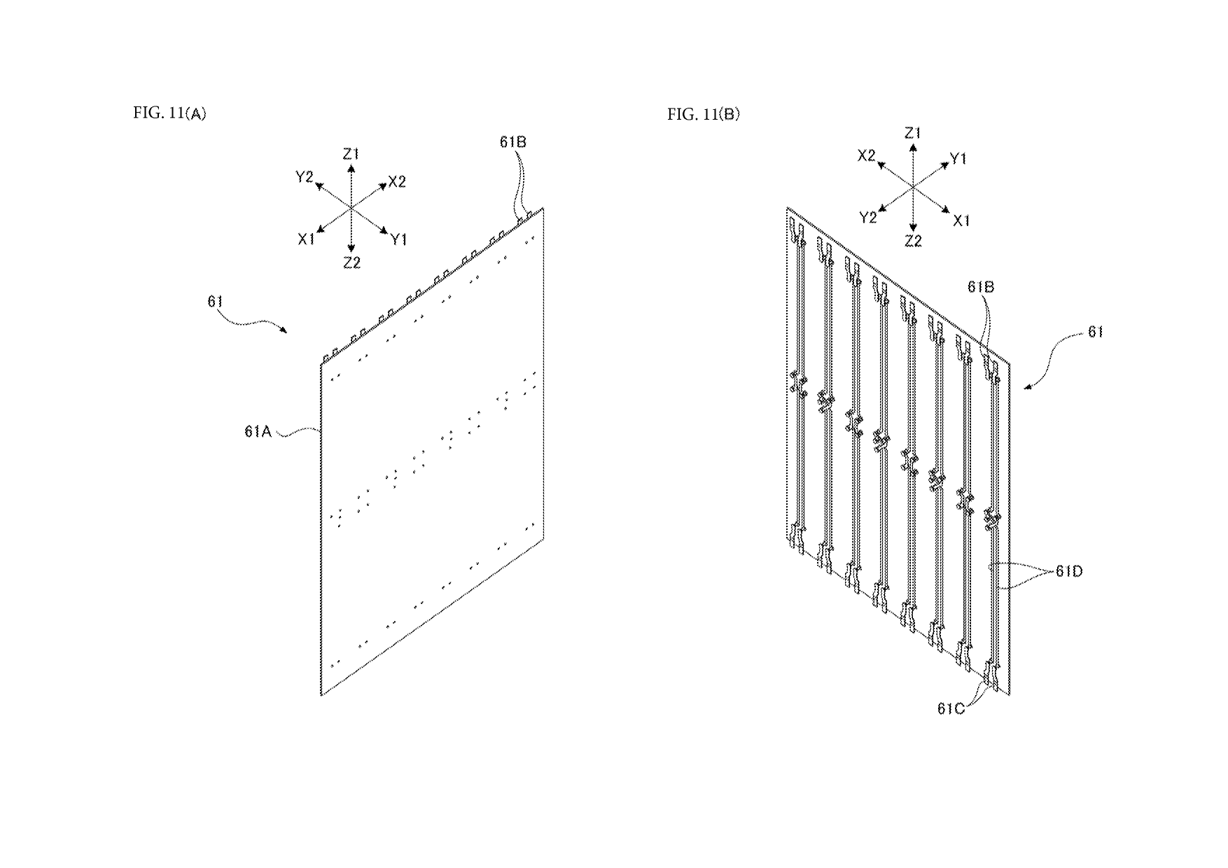

The substrate 61A is made of an electrically insulating material such as plastic, and is disposed such that the major faces thereof are at right angles to the Y-axis direction. The substrate 61A is formed of three layers in the Y-axis direction, and, in FIG. 11(A) and FIG. 11(B), the Y1 and Y2 layers have been omitted and only the middle layer is shown. In addition, illustrations of the ground portions 61E that cover, respectively, the Y1 surface of the substrate, i.e., the Y1 layer, and the Y2 surface of the substrate, i.e., the Y2 layer, have been omitted in FIG. 11(A) and FIG. 11(B).

Multiple (in the present embodiment, six) pad pairs for the first connector 61B are formed in the top portion of the substrate 61A. Multiple (in the present embodiment, six) pad pairs for the second connector 61C are formed in the bottom portion of the substrate 61A. In the present embodiment, as shown in FIG. 11(B), all pad pairs for the first connector 61B and pad pairs for the second connector 61C are arranged side by side in the X-axis direction on the Y2 major face of the Y2 layer (not shown) of the substrate 61A. Therefore, as shown in FIG. 11(A), no pad pairs for the first connector 61B or pad pairs for the second connector 61C are formed on the Y1 layer (not shown) of the substrate 61A.

The trace pairs 61D are multiple (in the present embodiment, six) pairs of electrically conductive patterns formed on the Y1 major face of the middle layer of the substrate 61A. The multiple trace pairs 61D, which are formed of equal electrical length, extend in the up-down direction and connect the pad pairs for the first connector 61B and the pad pairs for the second connector 61C. The two traces in each trace pair 61D, as viewed in the Y-axis direction, are bent to intersect at an intermediate location in the up-down direction. The two traces are located differently in the Y-axis direction at the intersection point, and therefore do not come into contact with each other. The trace pairs 61D are connected by vias to the pad pairs for the first connector 61B and the pad pairs for the second connector 61C that correspond thereto.

The ground portions 61E are provided to cover most of the respective major faces of the substrate 61A. At such time, neither the pad pairs for the first connector 61B nor the pad pairs for the second connector 61C are covered by the ground portions 61E.

The thus configured intermediate boards for connectors 61 are mated with the first connector 10 in the top portion. At such time, the intermediate boards for connectors 61 are connected to the signal contact portions of the signal terminal pairs of the first connector 10 by means of the pad pairs for the first connector 61B, and are connected to the ground contact portions of the ground members of the first connector 10 by means of the ground portions 61E. In addition, the intermediate boards for connectors 61 are mated with the second connector 20 in the bottom portion. At such time, the intermediate boards for connectors 61 are connected to the signal contact portions of the signal terminal pairs 21B of the second connector 20 by means of the pad pairs for the second connector 61C, and are connected to the ground contact portions of the ground members 21C, 21D of the second connector 20 by means of the ground portions 61E. In this manner, the intermediate boards for connectors 61 are adapted to relay an electrical connection between the first connector 10 and second connector 20.

The housing 70, which is made of plastic or another electrically insulating material, is of a generally rectangular parallelepiped-like external shape. As shown in FIG. 5 and FIG. 6, the housing 70 includes a lower housing 71 and an upper housing 72, which are formed by being divided in the up-down direction.

The lower housing 71 has formed therein a lower accommodating space 71A used to receive from above and accommodate the respective bottom portions of the intermediate bodies 40, 50, 60. A notched portion 71C (a portion of the lower accommodating space 71A), which is cut out to be upwardly open, is formed in the front wall portion 71B of the lower housing 71. Accordingly, as shown in FIG. 3, all cables C connected to the intermediate bodies for cables 40, 50 are adapted to project forwardly (in the X1 direction) out of the lower housing 71 once the bottom portions of the intermediate bodies for cables 40, 50 have been accommodated in the lower accommodating space 71A.

As shown in FIG. 6, a lower receiving space 71D used to receive from below and accommodate the second connector 20 is formed in the bottom portion of the lower housing 71. In addition, in the lower housing 71, slit aperture portions 71F, which extend in the up-down direction while extending in the forward-backward direction, are formed in an intervening wall 71E separating the lower accommodating space 71A and the lower receiving space 71D in the up-down direction. Once the respective bottom portions of the intermediate bodies 40, 50, 60 have been accommodated in the lower accommodating space 71A, the respective bottom end portions of the first intermediate board for cables 41, the second intermediate board for cables 51, and the intermediate boards for connectors 61 (hereinafter referred to collectively as “intermediate boards 41, 51, 61”) project downwardly from the slit aperture portions 71F and are positioned in the lower receiving space 71D. As a result, the intermediate boards 41, 51, 61 are adapted to be matable with the second connector 20.

As shown in FIG. 5 and FIG. 6, the upper housing 72, which is configured in a manner analogous to the previously discussed lower housing 71, is disposed in an orientation that is vertically flipped relative to the lower housing 71. In FIG. 5 and FIG. 6, the sections of the upper housing 72 that correspond to sections in the lower housing 71 are assigned reference numerals obtained by adding “1” to the reference numerals used in said lower housing 71.

The upper housing 72 differs from the lower housing 71 in that it does not have a section corresponding to the notched portion 71C of the lower housing 71. In addition, multiple guiding groove portions 72H extending in the up-down direction are formed in a side-by-side arrangement in the Y-axis direction in the respective inner surfaces of the front wall portion 72B and rear wall portion 72G of the upper housing 72. Along with being guided in the up-down direction by the guiding groove portions 72H, the intermediate boards 41, 51, 61 are precisely positioned in the Y-axis direction by the interior surface of the grooves.

In an upper accommodating space 72A, the upper housing 72 receives from below and accommodates the top portions of the intermediate bodies 40, 50, 60, i.e., the respective top portions of the top portions of the intermediate boards 41, 51, 61. In addition, in an upper receiving space 72D, the upper housing 72 receives from above and accommodates the first connector 10. In addition, the top end portions of the intermediate boards 41, 51, 61 project from slit aperture portions 72F and are positioned in the upper receiving space 72D. As a result, the intermediate boards 41, 51, 61 are adapted to be matable with the first connector 10.

The board coupler 5 has the same configuration as the previously discussed board coupler 4. A description of the board coupler 5 is omitted herein.

In the same manner as the board coupler 4, the board coupler 6 has a first connector, a second connector, and an intermediate connector. The first connector and the second connector of the board coupler 6 have the same configuration as the first connector 10 and the second connector 20 of the board coupler 4. The configuration of the intermediate connector of the board coupler 6 differs from the intermediate connector 30 of the board coupler 4 in that it has no first intermediate body for cables and no second intermediate body for cables, and only has intermediate bodies for connectors. The intermediate bodies for connectors of the board coupler 6 have the same configuration as the intermediate bodies for connectors 60 of the board coupler 4. The number of the intermediate bodies for connectors 60 provided in the board coupler 6 can be set as appropriate.

In the first connector provided in the board coupler 6, in all terminal retainers connected to the intermediate boards for connectors of the intermediate connector, the signal connection portions of the signal terminals are solder-connected to the signal circuitry of the first circuit board P1. This signal circuitry is connected to the first light modules 1. In addition, in the second connector provided in the board coupler 6, in all terminal retainers connected to the intermediate boards for connectors of the intermediate connector, the signal connection portions of the signal terminals are solder-connected to the signal circuitry of the second circuit board P2. This signal circuitry is connected to the ASIC 3.

As shown in FIG. 1 and FIG. 2, the counterpart connector 7 is connected to the board coupler 4 via two flat cables F. The number of the flat cables F connecting the counterpart connector 7 and the board coupler 4 can be set as appropriate; for example, there can be one cable, or there can be three or more cables. In addition, although in the present embodiment there are two flat cables F connected to a single counterpart connector 7, as an alternative, for example, the flat cables and the same number of counterpart connectors (counterpart connection portions) can be used to connect respective flat cables to respective counterpart connectors, i.e., in a manner to connect one flat cable to one counterpart connector.

A configuration in which the counterpart connector 7 is connected to the board coupler 4 by a single cable is described hereinbelow for the purpose of convenience in description. It should be noted that a description of the counterpart connector 8 is omitted herein because it has the same configuration as the counterpart connector 7.

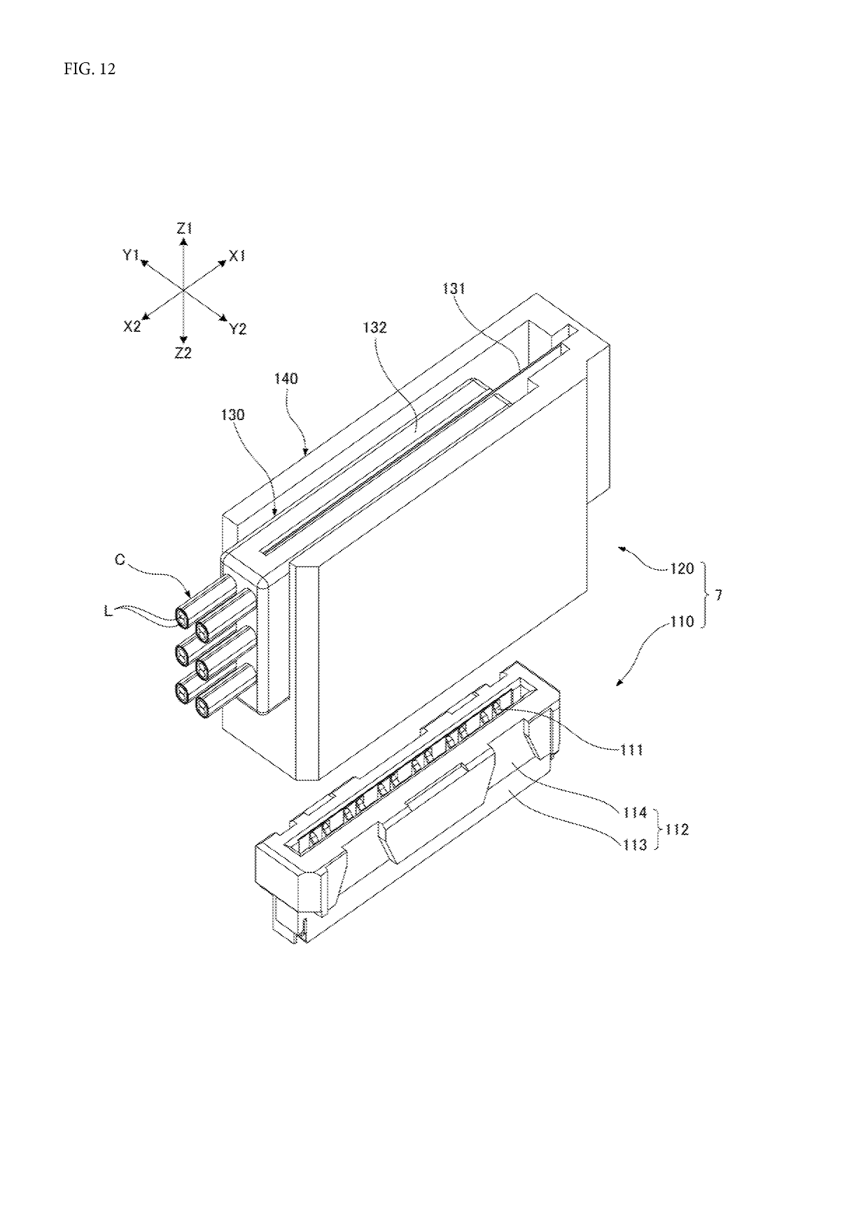

As shown in FIG. 12, the counterpart connector 7 has one counterpart board connector 110, which is mounted on the second circuit board P2, and one counterpart intermediate connector 120, which is matingly connected to the counterpart board connector 110 from above.

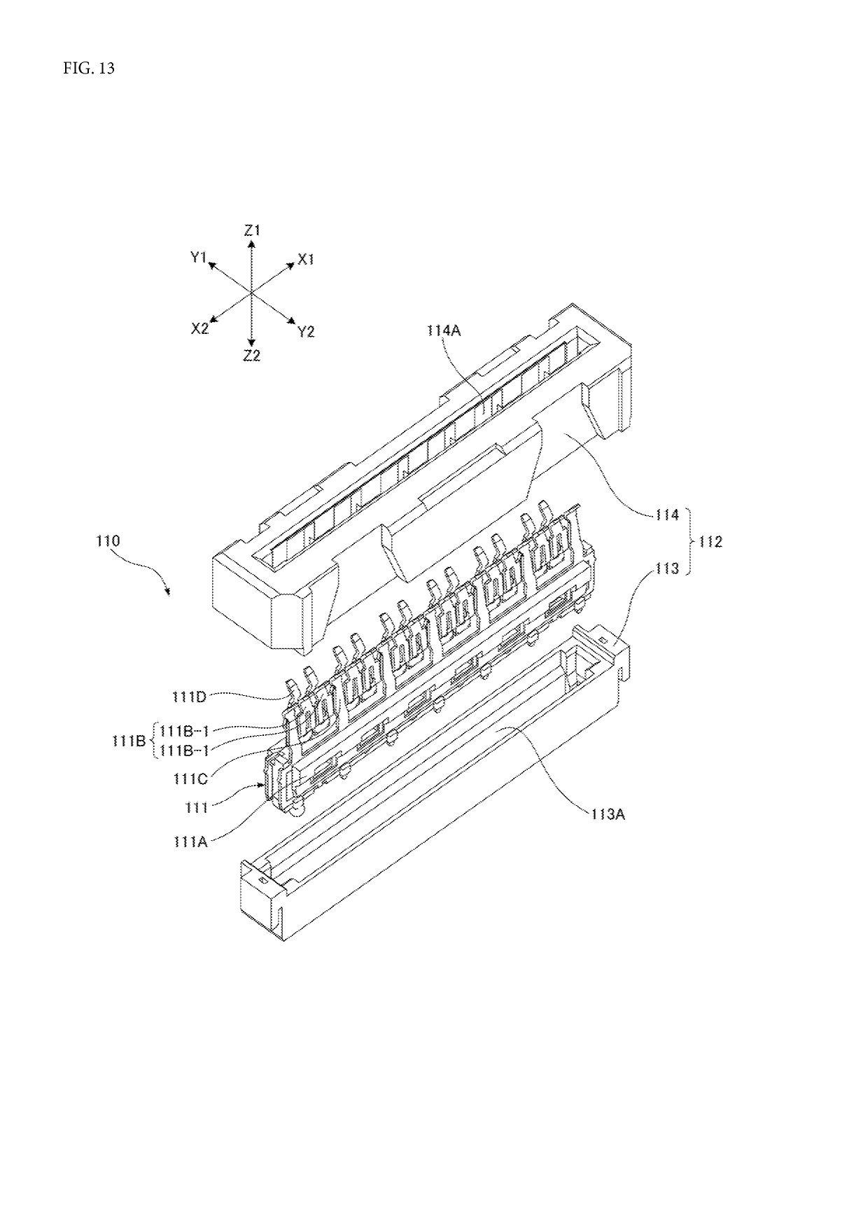

As shown in FIG. 12, the counterpart board connector 110 is of a generally rectangular parallelepiped-like external shape whose longitudinal direction is the forward-backward direction (X-axis direction). As shown in FIG. 13, the counterpart board connector 110 has a single terminal retainer 111, and a counterpart housing 112 accommodating and retaining these terminal retainers 111.

The terminal retainer 111 has the same configuration as the terminal retainers 21 of the second connector 20. With respect to the configuration of the terminal retainer 111, the sections that correspond to the components of the terminal retainers 21 are assigned reference numerals obtained by adding “90” to the reference numerals used for the terminal retainers 21, and a description thereof is omitted.

The counterpart housing 112 is made of plastic or another electrically insulating material and, as shown in FIG. 12, is of a generally rectangular parallelepiped-like external shape. As shown in FIG. 13, the counterpart housing 112 includes a lower housing 113 and an upper housing 114, which are formed by being divided in the up-down direction. In the lower housing 113, there is formed a lower accommodating space 113A which, along with passing through the lower housing 113 in the up-down direction (Z-axis direction), extends in the X-axis direction. The lower housing 113 receives from above and accommodates the bottom portion of the terminal retainer 111. At such time, the terminal retainer 111 is press-fitted into and retained within the lower accommodating space 113A by the ends of both ground members 111C, 111D.

In the upper housing 114, there is formed an upper accommodating space 114A which, along with passing through the upper housing 114 in the up-down direction (Z-axis direction), extends in the X-axis direction. The upper accommodating space 114A receives from below and accommodates the top portion of the terminal retainer 111, or more specifically, the signal contact portions of the signal terminal pairs 111B and the ground contact portions of the ground members 111C, 111D. The upper accommodating space 114A also serves as a receiving space which receives, from above, the bottom end portion of the hereinafter described counterpart intermediate board 131.

As shown in FIG. 12, the counterpart intermediate connector 120 has a counterpart intermediate body 130, to which cables C are connected, and a counterpart intermediate housing 140, which accommodates and retains the counterpart intermediate body 130. The counterpart intermediate body 130 is of a generally plate-like configuration and is disposed in such an orientation that the major faces thereof are at right angles to the Y-axis direction. The cables C connected to the counterpart intermediate body 130 project rearwardly (in the X2 direction).

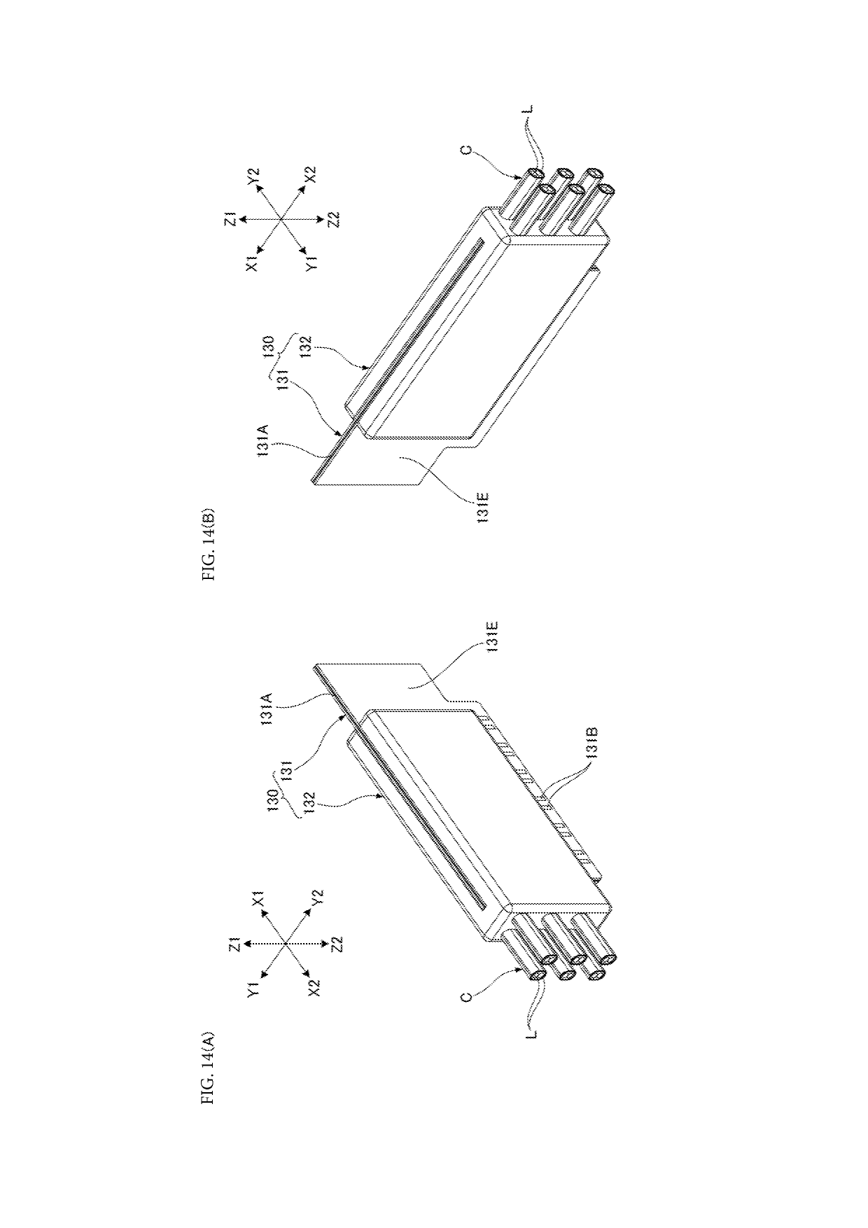

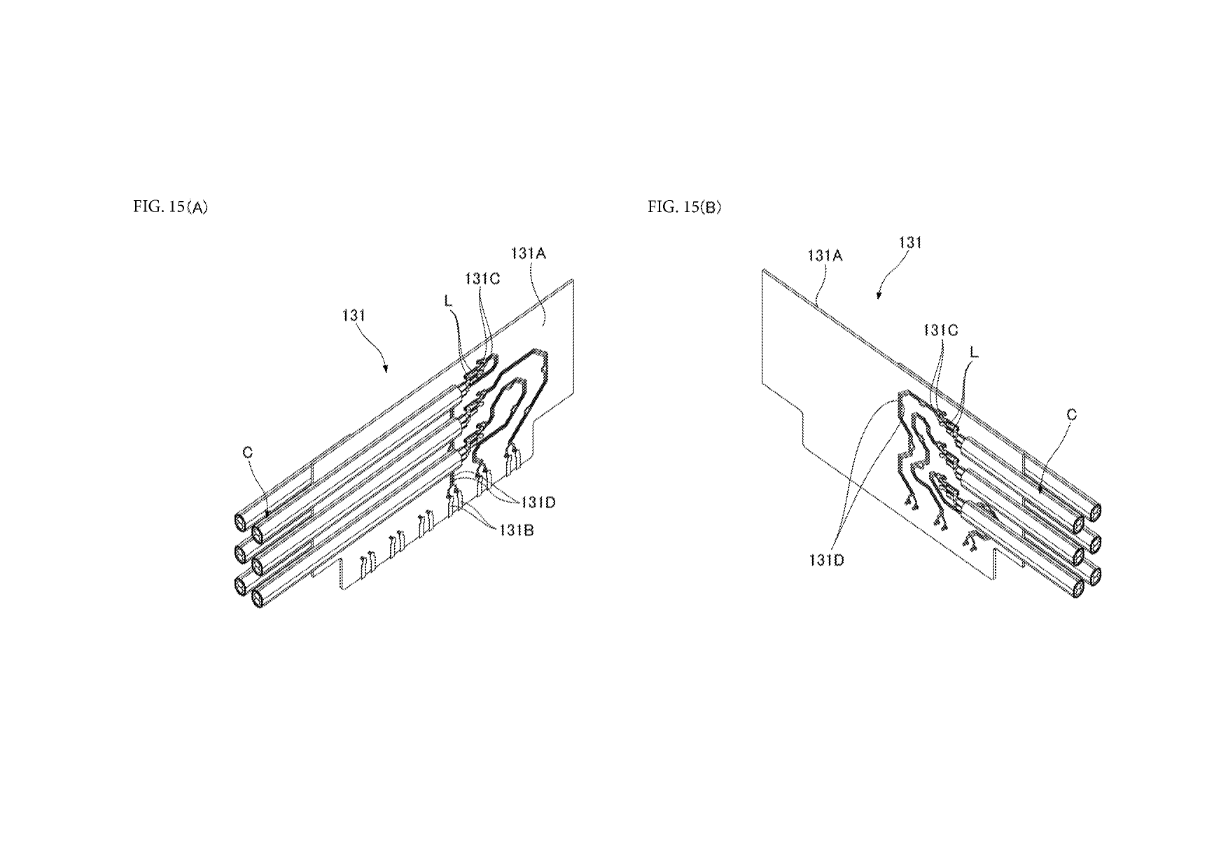

As shown in FIG. 14(A) and FIG. 14(B), the counterpart intermediate body 130 has a counterpart intermediate board 131 (an intermediate member for linear bodies), to which the cables C are connected, and a board retaining member 132, which retains the counterpart intermediate board 131. As shown in FIG. 15(A) and FIG. 15(B), the counterpart intermediate board 131 is configured by omitting the top portion of the second intermediate board for cables 51 of the second intermediate body for cables 50, or more specifically, the section projecting upwardly from the board retaining member 52.

The counterpart intermediate board 131 has a plate-shaped substrate 131A made of plastic or another electrically insulating material, multiple pad pairs for counterpart connectors 131B, multiple pad pairs for cables 131C, multiple trace pairs 131D, and two ground portions 131E (see FIG. 14(A) and FIG. 14(B)). The substrate 131A, the pad pairs for counterpart connectors 131B, the pad pairs for cables 131C, and the trace pairs 131D have the same configuration as the substrate 51A of the second intermediate board for cables 51, the pad pairs for the second connector 51B, the pad pairs for cables 51C, and the trace pairs 51D.

The board retaining member 132, which has the same configuration as the board retaining member 52 of the second intermediate body for cables 50, is integrally molded with the counterpart intermediate board 131 in a manner to cover most of said counterpart intermediate board 131. In addition, in the rear portion, the board retaining member 132 embeddedly retains the ends of the cables C. The bottom end portion of the counterpart intermediate board 131 protrudes downwardly from the board retaining member 132, as a result of which the pad pairs for counterpart connectors 131B located in said bottom end portion are adapted to be contactable with the signal terminal pairs 111B of the counterpart board connector 110. In addition, the ground portions 131E that cover the bottom end portion of the counterpart intermediate board 131 are adapted to be contactable with the ground members 111C, 111D of the counterpart board connector 110.

As shown in FIG. 1, in the present embodiment, the first circuit board P1 and the second circuit board P2 are coupled by the board couplers 4, 5, 6, and the intermediate bodies for cables 40, 50 of the board couplers 4, 5 are respectively connected to the corresponding counterpart connectors 7, 8 (counterpart connection portions) via the flat cables F.

In the board couplers 4, 5, the pad pairs for the first connector 41B of the first intermediate body for cables 40 are connected directly to the signal terminal pairs of the first connector 10, thereby electrically connecting the first connector 10 and the counterpart connector 7 via the pad pairs for the first connector 41B, the trace pairs 41D, the pad pairs for cables 41C, and the flat cables F. As a result, signal transmission paths are formed between the first light modules 1 and the ASIC 3 by the circuitry of the first circuit board P1, the board couplers 4, 5, the flat cables F, the counterpart connectors 7, 8, and the circuitry of the second circuit board P2, such that the first light modules 1 and the ASIC 3 become electrically connected.

In addition, the ground portions 41E of the first intermediate body for cables 40 are connected directly to the ground members of the first connector 10 and the ground members 21C, 21D of the second connector 20, thereby forming a ground transmission path between the first circuit board P1 and the second circuit board P2.

The pad pairs for the second connector 51B of the second intermediate body for cables 50 are connected directly to the signal terminal pairs 21B of the second connector 20, thereby electrically connecting the second connector 20 and the counterpart connector 7 via the pad pairs for the second connector 51B, the trace pairs 51D, the pad pairs for cables 51C, and the flat cables F. As a result, signal transmission paths are formed between the second light modules 2 and the ASIC 3 by the circuitry of the second circuit board P2, the board couplers 4, 5, the flat cables F, the counterpart connectors 7, 8, and other circuitry on the second circuit board P2, such that the second light modules 2 and the ASIC 3 become electrically connected.

In addition, the ground portions 51E of the second intermediate body for cables 50 are connected directly to the ground members of the first connector 10 and the ground members 21C, 21D of the second connector 20, thereby forming a ground transmission path between the first circuit board P1 and the second circuit board P2.

In addition, the pad pairs for the first connector 61B of the intermediate bodies for connectors 60 are connected directly to the signal terminal pairs of the first connector 10, and the pad pairs for the second connector 61C are connected directly to the signal terminal pairs 21B of the second connector 20, thereby electrically connecting the first connector 10 and the second connector 20 via the pad pairs for the first connector 61B, the trace pairs 61D, and the pad pairs for the second connector 61C. As a result, signal transmission paths are formed between the first light modules 1 and the ASIC 3 by the circuitry of the first circuit board P1, the board couplers 4, 5, and the circuitry of the second circuit board P2, such that the first light modules 1 and the ASIC 3 become electrically connected.

In addition, the ground portions 61E of the intermediate bodies for connectors 60 are connected directly to the ground members of the first connector 10 and the ground members 21C, 21D of the second connector 20, thereby forming a ground transmission path between the first circuit board P1 and the second circuit board P2.

In addition, in the board coupler 6, the pad pairs for the first connector of the intermediate bodies for connectors are connected directly to the signal terminal pairs of the first connector, and the pad pairs for the second connector are connected directly to the signal terminal pairs of the second connector, thereby electrically connecting the first connector and the second connector via the pad pairs for the first connector, the trace pairs, and the pad pairs for the second connector. As a result, signal transmission paths are formed between the first light modules 1 and the ASIC 3 by the circuitry of the first circuit board P1, the board coupler 6, and the circuitry of the second circuit board P2, such that the first light modules 1 and the ASIC 3 become electrically connected.

In addition, the ground portions of the intermediate bodies for connectors are connected directly to the ground members of the first connector and the ground members of the second connector, thereby forming a ground transmission path between the first circuit board P1 and the second circuit board P2.

In general, loss due to heat generation occurring in cables is smaller than loss due to heat generation occurring in the circuit traces (electrically conductive patterns) of a circuit board. In the present embodiment, on the second circuit board P2, signals are transmitted via the cables C of the flat cables F respectively between the first intermediate body for cables 40 of the board coupler 4 and the counterpart connector 7 and, in addition, between the second intermediate body for cables 50 of the board coupler 4 and the counterpart connector 7. This is to say that a portion of the signal transmission paths between the intermediate connectors 30 and the ASIC 3 is formed by the cables C, in which heat generation is relatively small, and therefore loss occurring in the signal transmission path can be reduced even if the distance between the board coupler 4 and the ASIC 3 is increased. In addition, in the present embodiment, the counterpart connector 7 is mounted in closer proximity to the ASIC 3 than the board coupler 4. Accordingly, the circuitry that connects the counterpart connector 7 and the ASIC 3 on the second circuit board P2 can be shortened, which allows for loss in the signal transmission path to be further reduced. In addition, loss in the signal transmission path between the board coupler 5 and the counterpart connector 8 can be similarly reduced.

Although in the board coupler 6 the signal transmission path between the second connector and the ASIC 3 is formed by the circuitry of the second circuit board, the board coupler 6 is located in closer proximity to the ASIC 3 than the board couplers 4, 5, and therefore the length of the circuitry is relatively short and loss occurring in said circuitry is not very large.

In the present embodiment, the trace pairs 41D on the intermediate board for cables 41 have electrical lengths equal to each other and the trace pairs 51D on the intermediate board for cables 51 have electrical lengths equal to each other, and furthermore, the trace pairs 131D on the counterpart intermediate board 131 have electrical lengths equal to each other. In addition, the cables C, and thus the electrical wire pairs L, have lengths equal to each other. Accordingly, the lengths of the signal transmission paths formed by the trace pairs 41D, 131D and the electrical wire pairs L are equal across all signal transmission paths. Likewise, the lengths of the signal transmission paths formed by the trace pairs 51D, 131D and the electrical wire pairs L are equal across all signal transmission paths. As a result, while all of the cables C have the same length, stable differential signal transmission can be achieved. Accordingly, when cutting the cables C during the operation of connecting the intermediate boards for cables 41, 51 and the counterpart intermediate board 131, all cables C can simply be cut to the same length and there is no longer a need to cut the cables C to different lengths depending on the length of the connected traces, which simplifies the operation of cutting the cables C.

Although in the present embodiment the intermediate members (intermediate member for linear bodies and intermediate member for connectors) are intermediate boards, i.e., circuit boards in which first pad pairs, second pad pairs, and trace pairs are formed on a substrate, the configuration of the intermediate members is not limited thereto, and various modifications are possible. For example, members formed by retaining multiple terminal pairs made of sheet metal members in place on a substrate of plastic or another electrically insulating material by integral molding can be used as intermediate members.

Although in the present embodiment the cables C are twinax cables, as an alternative, it is possible to use, for example, coaxial cable pairs, FPC, or the like.

In the present embodiment, three types of intermediate boards, i.e., first intermediate boards for cables 41, second intermediate boards for cables 51, and intermediate boards for connectors 61, are provided in the board couplers 4, 5 among the board couplers 4, 5, 6. However, it is not essential to provide these three types of intermediate boards in the board couplers, and there can be a number of variations with regard to connections between the first light modules 1 and the ASIC 3, as well as to connections between the second light modules 2 and the ASIC 3. These variations will be described below.

### First Variation

In the above-described embodiment, some of the second light modules 2 among the multiple second light modules 2 are connected to one of the board couplers 4, 5 via the circuitry of the second circuit board P2, and the rest of the second light modules 2 are connected to the ASIC 3 via other circuitry on the second circuit board P2. As a variation on this embodiment (first variation), it is possible, for example, to perform signal transmission by connecting all second light modules 2 to one of the board couplers 4, 5 via the circuitry of the second circuit board P2. In this first variation, a portion of the signal transmission paths between all second light modules 2 and the ASIC 3 is formed by the cables C, and therefore loss can be reduced in all of these signal transmission paths.

### Second Variation

In the above-described embodiment, some of the first light modules 1 are connected to the ASIC 3 via intermediate boards for connectors provided in the intermediate connector of one of the board couplers. As a variation on this embodiment (second variation), it is possible, for example, to provide only first intermediate boards for cables and second intermediate boards for cables in the intermediate connectors of all board couplers. In this second variation, none of the intermediate connectors of any of the board couplers have intermediate boards for connectors. Consequently, all first light modules 1 are connected to the ASIC 3 via intermediate boards for the first connector, and thus the cables C. As a result, a portion of the signal transmission paths between all first light modules 1 and the ASIC 3 is formed by the cables C, and therefore loss can be reduced in all of these signal transmission paths.

### Third Variation

In the above-described second variation, some of the second light modules 2 among the multiple second light modules 2 are connected to one of the board couplers 4, 5 via the circuitry of the second circuit board P2, and the rest of the second light modules 2 are connected to the ASIC 3 via other circuitry on the second circuit board P2. As a variation on this second variation (third variation), it is possible, for example, to perform signal transmission by connecting all second light modules 2 to one of the board couplers 4, 5 via the circuitry of the second circuit board P2. In this third variation, a portion of the signal transmission paths between all second light modules 2 and the ASIC 3 is formed by the cables C, and therefore loss can be reduced in all of these signal transmission paths.

### Fourth Variation

In the above-described embodiment, some of the first light modules 1 among the multiple first light modules 1 are connected to the ASIC 3 via one of the first intermediate boards for cables provided in the intermediate connectors of the board couplers 4, 5, 6. As a variation on this embodiment (fourth variation), it is possible, for example, to provide no first intermediate boards for cables in the intermediate connectors of any board couplers and to provide intermediate boards for connectors in the intermediate connectors of at least some of the board couplers. In this fourth variation, all first light modules 1 are connected to the ASIC 3 via the intermediate boards for connectors of one of the board couplers, and thus the circuitry of the second circuit board P2. Since there are no first intermediate boards for cables in this fourth variation, the operation of connecting the first intermediate boards for cables to the cables is no longer required. In addition, if the board couplers having intermediate boards for connectors are disposed at locations in closest possible proximity to the ASIC 3, the above-mentioned circuitry of the second circuit board P2 will be shortened, thereby making it possible to keep loss in said circuitry to a minimum.

### Fifth Variation

In the above-described fourth variation, some of the second light modules 2 among the multiple second light modules 2 are connected to one of the board couplers 4, 5 via the circuitry of the second circuit board P2, and the rest of the second light modules 2 are connected to the ASIC 3 via other circuitry on the second circuit board P2. As a variation on this fourth variation (fifth variation), it is possible, for example, to perform signal transmission by connecting all second light modules 2 to one of the board couplers having a second intermediate board for cables via the circuitry of the second circuit board P2. In this fifth variation, a portion of the signal transmission paths between all second light modules 2 and the ASIC 3 is formed by the cables C, and therefore loss can be reduced in all of these signal transmission paths.

### Sixth Variation

In the above-described embodiment, some of the second light modules 2 among the multiple second light modules 2 are connected to the ASIC 3 via one of the second intermediate boards for cables provided in the intermediate connectors of the board couplers 4, 5. As a variation on this embodiment (sixth variation), it is possible, for example, to provide no second intermediate boards for cables in the intermediate connectors of any board couplers. In this sixth variation, all second light modules 2 are connected to the ASIC 3 via the circuitry of the second circuit board P2. Since there are no second intermediate boards for cables in this sixth variation, the operation of connecting the second intermediate boards for cables to the cables is no longer required. In addition, if the second light modules 2 are disposed at locations in closest possible proximity to the ASIC 3, the circuitry of the second circuit board P2 will be shortened, thereby making it possible to keep loss in said circuitry to a minimum.

### Seventh Variation

In the above-described sixth variation, some of the first light modules 1 among the multiple first light modules 1 are connected to the ASIC 3 via the intermediate boards for connectors provided in the intermediate connector of one of the board couplers. As a variation on this sixth variation (seventh variation), it is possible, for example, to provide only first intermediate boards for cables and second intermediate boards for cables in the intermediate connectors of all board couplers. In this seventh variation, none of the intermediate connectors of any of the board couplers have intermediate boards for connectors. Consequently, all first light modules 1 are connected to the ASIC 3 via intermediate boards for the first connector, and thus the cables C. As a result, a portion of the signal transmission paths between all first light modules 1 and the ASIC 3 is formed by the cables C, and therefore loss can be reduced in all of these signal transmission paths.

If the intermediate connectors of all board couplers have only intermediate boards for cables (at least either one of a first intermediate board for cables and a first intermediate board for cables), the second circuit board can be split into two circuit boards, or more specifically, a circuit board having the second light modules and the board couplers mounted thereon, and another circuit board having the ASIC and the counterpart connectors mounted thereon. In such a case, the cables are provided extending so as to span between the above-mentioned circuit board and the above-mentioned other circuit board. In addition, at such time, the above-mentioned circuit board and the above-mentioned other circuit board can be disposed at different locations in the up-down direction.

### Eighth Variation

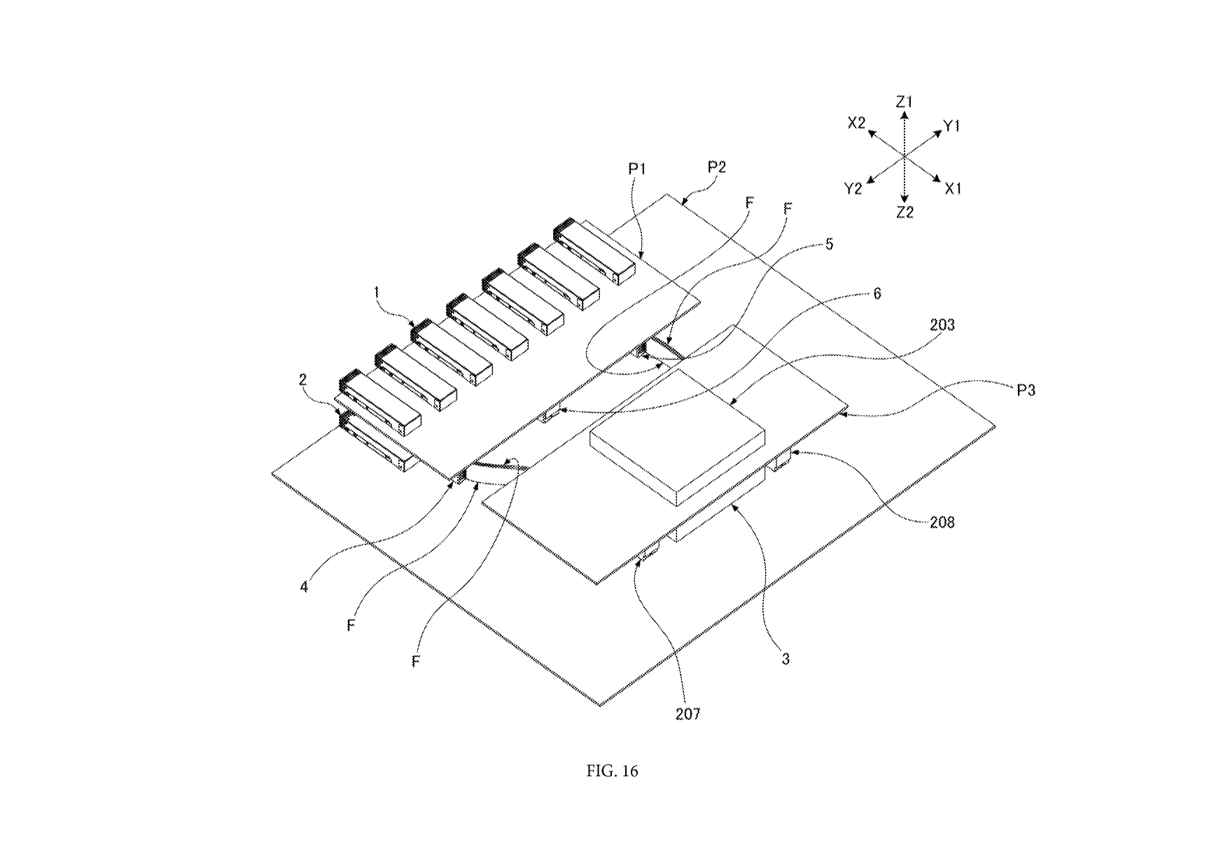

In the above-described embodiment and each of the variations, an example connection structure for electrically connecting first light modules 1 mounted on a first circuit board P1, second light modules 2 mounted on a second circuit board P2, and an ASIC 3 mounted on the second circuit board P2 has been described; however, as an alternative variation (eighth variation), it is possible, for example as shown in FIG. 16, to further provide a third circuit board P3, which has mounted thereon an ASIC 203 serving as a fourth electronic component. In this variation, the light modules 1, 2 are electrically connected not only to the ASIC 3, but also to the ASIC 203.

As shown in FIG. 16, the third circuit board P3 is disposed forwardly (on the X1 side) of the first circuit board P1 and, in addition, upwardly (on the Z1 side) of the second circuit board P2.

The third circuit board P3 is located at the same height in the up-down direction as the first circuit board P1. The ASIC 203, which is of the same shape as the ASIC 3, is mounted on the top face of the third circuit board P3 and positioned directly above the ASIC 3.

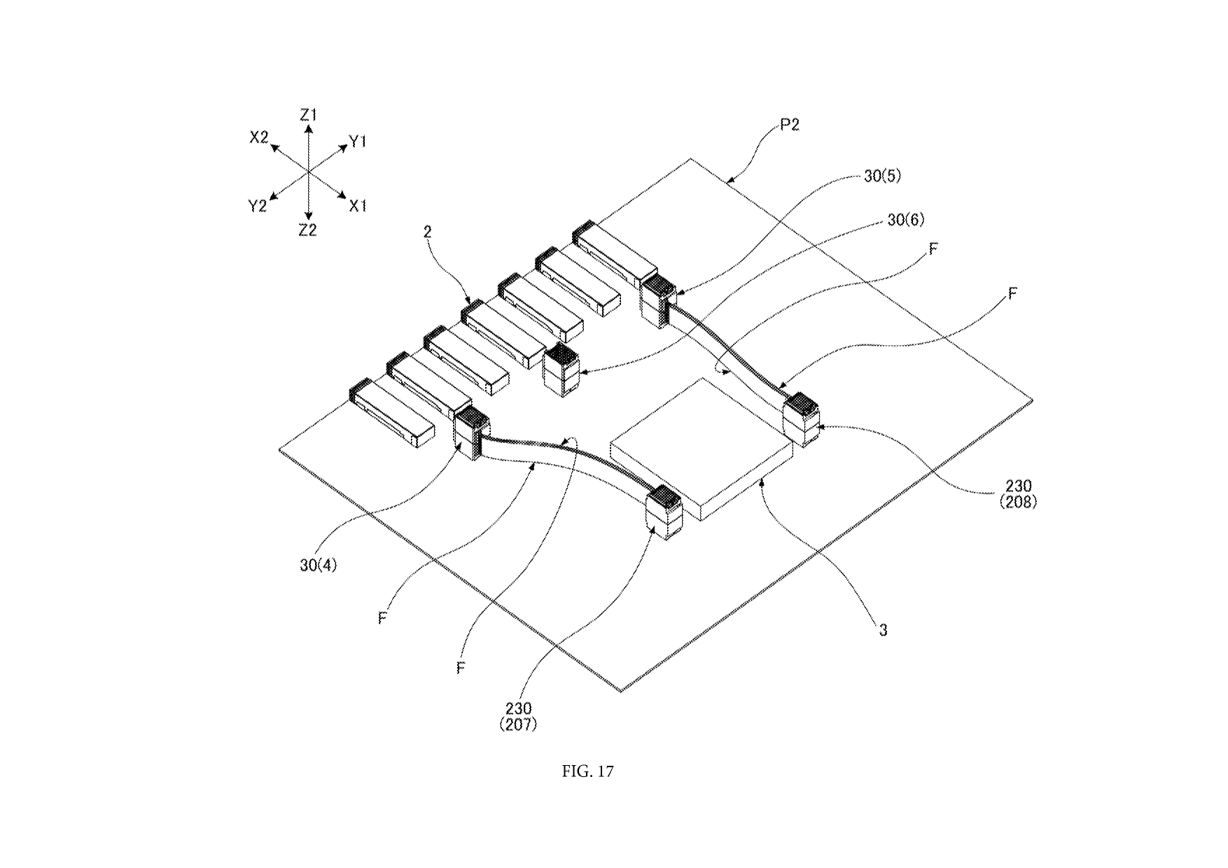

In this variation, the counterpart connectors 207, 208 are configured as board couplers coupling the second circuit board P2 and the third circuit board P3. As shown in FIG. 17, the counterpart connectors 207, 208, which are configured similarly to the board couplers 4, 5, have a first connector, i.e., an electrical connector for circuit boards, which is mounted on the bottom face of the third circuit board P3, a second connector, i.e., an electrical connector for circuit boards, which is mounted on the top face of the second circuit board P2, and an intermediate connector 230, which is interposed between the first connector and the second connector in the up-down direction.

In the counterpart connectors 207, 208, the first connector is connected to the ASIC 203 via the circuitry of the third circuit board P3, and the second connector is connected to the ASIC 3 via the circuitry of the second circuit board P2. In addition, in the same manner as the board couplers 4, 5, the intermediate connector 230 has three types of intermediate bodies, i.e., a first intermediate body for cables, a second intermediate body for cables, and intermediate bodies for connectors.

Along with being electrically connected to the first intermediate board for cables or the second intermediate board for cables of the board couplers 4, 5 via flat cables F, the first intermediate board for cables of the first intermediate body for cables of the counterpart connectors 207, 208 is mated with the first connector of the counterpart connectors 207, 208 and becomes electrically connected to said first connector. Along with being electrically connected to the first intermediate board for cables or the second intermediate board for cables of the board couplers 4, 5 via the flat cables F, the second intermediate board for cables of the second intermediate body for cables of the counterpart connectors 207, 208 is mated with the second connector of the counterpart connectors 207, 208 and becomes electrically connected to said second connector. Along with mating with the first connector of the counterpart connectors 207, 208 and becoming electrically connected to said first connector, the intermediate bodies for connectors (intermediate boards for connectors) of the counterpart connectors 207, 208 are mated with the second connector of the counterpart connectors 207, 208 and become electrically connected to said second connector.

The connection structure of this variation allows for the light modules 1, 2 and the ASICs 3, 203 to be electrically connected and thus enables signal transmission (in this variation, differential signal transmission) between the light modules 1, 2 and the ASICs 3, 203. In this variation, the third circuit board P3 is formed as a separate component from the first circuit board P1; however, it may instead be formed as a single piece with the first circuit board P1.

### DESCRIPTION OF THE REFERENCE NUMERALS

1 First light module (first electronic component)

2 Second light module (third electronic component)

3 ASIC (second electronic component)

4 Board coupler

5 Board coupler

6 Board coupler

7 Counterpart connector (counterpart connection portion)

8 Counterpart connector (counterpart connection portion)

10 First connector

20 Second connector

21C First ground member (corresponding ground portion)

21D Second ground member (corresponding ground portion)

30 Intermediate connector

41 First intermediate board for cables (intermediate member for linear bodies)

41E Ground portion

51 Second intermediate board for cables (intermediate member for linear bodies)

51E Ground portion

61 Intermediate board for connectors (intermediate member for connectors)

61E Ground portion

P1 First circuit board

P2 Second circuit board

L Wire pair (signal transmission line)

C Cable (linear body)

1. An electrical connection structure for electronic components is a connection structure that electrically connects a first electronic component mounted on a first circuit board and a second electronic component mounted on a second circuit board, and also electrically connects the second electronic component and a third electronic component mounted on the second circuit board, wherein:
the first circuit board and the second circuit board are coupled by at least one board coupler;
the board coupler comprises a first connector mounted on the first circuit board, a second connector mounted on the second circuit board, and an intermediate connector interposed between the first connector and the second connector;
the first electronic component is connected to the first connector via circuitry provided on the first circuit board;
the intermediate connector of the at least one board coupler comprises at least one intermediate member for linear bodies;
a counterpart connection portion corresponding to the intermediate member for linear bodies is mounted on the second circuit board at a location in closer proximity to the second electronic component than the board coupler;
the intermediate member for linear bodies, while being connected directly to the first connector, is connected to the counterpart connection portion via a linear body having a signal transmission line;
the counterpart connection portion is connected to the second electronic component via circuitry provided on the second circuit board; and
the third electronic component is connected to the second electronic component via circuitry provided on the second circuit board.

2. The electrical connection structure for electronic components according to claim 1, wherein the intermediate connector comprises, in addition to the intermediate member for linear bodies, at least one intermediate member for connectors;
the intermediate member for connectors is connected directly to the first connector and the second connector; and
the second connector is connected to the second electronic component via circuitry provided on the second circuit board.

3. The electrical connection structure for electronic components according to claim 1, wherein there are provided a plurality of third electronic components,
some of the third electronic components are connected to the second electronic component via circuitry provided on the second circuit board;
the rest of the third electronic components are connected to the second connector via circuitry provided on the second circuit board;
the intermediate connector comprises, in addition to the intermediate member for linear bodies, at least one other type of intermediate member for linear bodies of a different kind from said intermediate member for linear bodies;
another counterpart connection portion corresponding to the other type of intermediate member for linear bodies is mounted on the second circuit board at a location in closer proximity to the second electronic component than the board coupler;
the other type of intermediate member for linear bodies, while being connected directly to the second connector, is connected to the other counterpart connection portion via a linear body; and
the other counterpart connection portion is connected to the second electronic component via circuitry provided on the second circuit board.

4. An electrical connection structure for electronic components is a connection structure that electrically connects a first electronic component mounted on a first circuit board and a second electronic component mounted on a second circuit board, and also electrically connects the second electronic component and a third electronic component mounted on the second circuit board, wherein:
the first circuit board and the second circuit board are coupled by at least one board coupler;
the board coupler comprises a first connector mounted on the first circuit board, a second connector mounted on the second circuit board, and an intermediate connector interposed between the first connector and the second connector;
the first electronic component is connected to the first connector via circuitry provided on the first circuit board;
the intermediate connector of the at least one board coupler comprises at least one intermediate member for connectors and at least one intermediate member for linear bodies;
a counterpart connection portion corresponding to the intermediate member for linear bodies is mounted on the second circuit board at a location in closer proximity to the second electronic component than the board coupler;
the intermediate member for connectors is connected directly to the first connector and the second connector;
the second connector is connected to the second electronic component via circuitry provided on the second circuit board;
the third electronic component is connected to the second connector via circuitry provided on the second circuit board;
the intermediate member for linear bodies, while being connected directly to the second connector, is connected to the counterpart connection portion via a linear body having a signal transmission line; and
the counterpart connection portion is connected to the second electronic component via circuitry provided on the second circuit board.

5. The electrical connection structure for electronic components according to claim 4, wherein there are provided a plurality of third electronic components,
some of the third electronic components are connected to the intermediate member for linear bodies via the second connector; and
the rest of the third electronic components are connected to the second electronic component via circuitry provided on the second circuit board.

6. An electrical connection structure for electronic components that is a connection structure that electrically connects a first electronic component mounted on a first circuit board and a second
electronic component mounted on a second circuit board, and also electrically connects the second electronic component and a third electronic component mounted on the second circuit board, wherein:
the first circuit board and the second circuit board are connected by at least one board coupler;
the board coupler comprises a first connector mounted on the first circuit board, a second connector mounted on the second circuit board, and an intermediate connector interposed between the first connector and the second connector;
the first electronic component is connected to the first connector via circuitry provided on the first circuit board;
the intermediate connector of the at least one board coupler comprises at least one of each of two types of intermediate member for linear bodies;
a counterpart connection portion corresponding to each type of intermediate member for linear bodies is mounted on the second circuit board at a location in closer proximity to the second electronic component than the board coupler;
of the two types of intermediate member for linear bodies, one type of intermediate member for linear bodies, while being connected directly to the first connector, is connected to the counterpart connection portion via a linear body having a signal transmission line;
the other type of intermediate member for linear bodies, while being connected directly to the second connector, is connected to the counterpart connection portion via a linear body having a signal transmission line;
the third electronic component is connected to the second connector via circuitry provided on the second circuit board; and
the counterpart connection portion is connected to the second electronic component via circuitry provided on the second circuit board.

7. The electrical connection structure for electronic components according to claim 6 wherein the intermediate connector comprises, in addition to the two types of intermediate member for linear bodies, at least one intermediate member for connectors;
the intermediate member for connectors is connected directly to the first connector and the second connector;
the second connector is connected to the second electronic component via circuitry provided on the second circuit board;
there are provided a plurality of first electronic components;
some of the first electronic components are connected to the one type of intermediate member for linear bodies via the first connector; and
the rest of the first electronic components are connected to the intermediate member for connectors via the first connector.

8. The electrical connection structure for electronic components according to claim 6, wherein there are provided a plurality of third electronic components;
some of the third electronic components are connected to the other type of intermediate member for linear bodies via the second connector; and
the rest of the third electronic components are connected to the second electronic component via circuitry provided on the second circuit board.
